(19) United States
(12) Patent Application Publication
(10) Pub. No.: US 2018/0087164 A1
(43) Pub. Date: Mar. 29, 2018

(54) TUNING ELECTRODE SURFACE ELECTRONICS WITH THIN LAYERS

(71) Applicant: California Institute of Technology, Pasadena, CA (US)

(72) Inventors: Cody E. Finke, Seattle, WA (US); Michael R. Hoffmann, South Pasadena, CA (US); Justin Jasper, Pasadena, CA (US); Laleh Majari Kasmaee, Pacific Palisades, CA (US); Stefan Omelchenko, Los Angeles, CA (US)

(21) Appl. No.: 15/718,943

(22) Filed: Sep. 28, 2017

Related U.S. Application Data
(60) Provisional application No. 62/401,045, filed on Sep. 28, 2016.

(51) Int. Cl. C25B 11/04; C02F 1/467; C02F 1/461; C25B 1/04; C25B 1/26

(52) U.S. Cl. CPC C25B 11/0452; C02F 1/4674; C02F 1/46109; C25B 1/04; C23C 16/405; C25B 11/0405; C25B 11/0415; C02F 2001/46142; C25B 1/26

(57) ABSTRACT

The disclosure provides for thin films that can be used to tune the catalytic characteristics of heterogeneous electrocatalysts.

### CROSS REFERENCE TO RELATED APPLICATIONS

This application claims priority under 35 U.S.C. § 119 from Provisional Application Ser. No. 62/401,045 filed Sep. 28, 2016, the disclosure of which is incorporated herein by reference.

### TECHNICAL FIELD

The disclosure provides for thin films that can be used to tune the catalytic characteristics of heterogeneous electrocatalysts.

### BACKGROUND

Catalysts act by reducing the activation energy to perform a chemical reaction by destabilizing intermediates and stabilizing transition states. The Sabatier principle states that an effective catalyst must bind a precursor just right. Too tight binding of a precursor or too loose binding of products/intermediates will prevent conversion to product/intermediates while too tight binding of product/intermediates or too loose binding of precursor will foul the catalyst preventing release of product or initiation of catalysis (see FIG. 2). All catalysts (including biological and heterogeneous) contain an active site or sites which provide the specific requirements for the “just right” binding of a precursor. In general, the two ways to tune an active site for “just right” binding are through either altering charge distribution (electronics) or steric hindrance (sterics) (see FIG. 3). With heterogeneous electrocatalysts, the reactant-catalyst binding sites' charge density is important for catalytic activity, yet there is no known way to sufficiently tune this parameter.

### SUMMARY

The disclosure provides for creating heterogeneous electrocatalysts by layering one or more thin films of one or more electrocatalytic materials onto the surface of a different electrocatalytic material or substrate, whereby catalytic characteristics of heterogeneous electrocatalysts can be tuned based upon the composition and/or thickness of the applied film. As evidenced herein, the performance of the chlorine evolution reaction (CER) and oxygen evolution reaction (OER) catalysts, IrO₂, RuO₂, and FTO, can be tuned by depositing thin films of TiO₂ using atomic layer deposition (ALD). In particular, by using the methods of disclosure it was found that the electrocatalytic performance of IrO₂ and RuO₂ for the Oxygen Evolution Reaction can be greatly improved by depositing a thin film of TiO₂ on their surfaces, so much so that the specific catalytic activity (i₀) and overpotential of these catalysts were tuned to an order of magnitude better than any previously reported catalyst for the OER in 1 M H₂SO₄. The improvement of electrocatalytic performance was attributed to a favorable change in the electrocatalysts' surface species' charge density. Moreover, the surface species' charge density of all catalyst studied was found to be predictably tunable based upon the thickness of the TiO₂ layer. Accordingly, the methods of the disclosure are directed to a platform technology that in principle can be used to rationally design heterogeneous electrocatalysts that can be used in many types of reactions where reactants are electrocatalytically converted into products. In other words, the results presented herein merely demonstrate an example of how the methods of disclosure can be used, not that the methods of the disclosure are limited to only creating chlorine evolution reaction (CER) electrocatalysts or oxygen evolution reaction (OER) electrocatalysts.

In a particular embodiment, the methods of the disclosure provide for the use of multiple (2 or more) electrocatalytic materials and layering them in thin layers on top of the surface of a different electrocatalytic material or substrate. In a further embodiment, the top or outermost electrocatalytic layer is less than 50 nm in thickness. As demonstrated herein, numerous heterogeneous electrocatalysts (>50) were created for 2 different industrially important reactions, the chlorine evolution reaction (CER) and the oxygen evolution reaction (0ER). In particular, multiple different materials (e.g., fluorine doped tin oxide (FTC)), iridium oxide (IrOₓ), ruthenium oxide (RuOₓ), and titania (TiOₓ)) were utilized in the methods disclosed herein to create new heterogeneous electrocatalysts. By using the methods of the disclosure, new heterogeneous electrocatalysts were created for OER which operated at lower or equal overpotentials (corrected for electrochemically active surface area) than any previously reported electrocatalyst using the industry standard OER conditions. For example, the current best electrocatalyst for the OER in 1 M H₂SO₄ is RuO₂ which operates at a specific activity (normalized to electrochemically active surface area) of 0.42 mA/cm² at 350 mV overpotential. By using the methods presented herein, a new heterogeneous electrocatalyst was made by layering 10 cycles of TiO₂ onto IrOₓ. This heterogeneous electrocatalyst was found to operate at a specific activity of 3.5 mA/cm² at 350 mV overpotential. Further, a new heterogeneous electrocatalyst made by layering 10 cycles of TiOₓ onto RuO₂ using the methods of the disclosure, yielded a heterogeneous electrocatalyst that operated at of 2.8 mA/cm² at 350 mV overpotential for the OER.

In a particular embodiment, the disclosure provides for a method to manufacture a heterogeneous electrocatalyst that has improved electrocatalytic activity for an electrochemical reaction, comprising, consisting essentially of, or consisting of: layering or depositing one or more thin films of one or more conductive and/or semiconductive catalytic materials onto a surface of a conductive electrocatalytic substrate by using 1 to 100 cycles of an atomic layer deposition process, wherein the composition of the one of more thin films is different from the composition of the conductive electrocatalytic substrate, wherein the number of cycles of the atomic layer deposition process is used to tune the electrocatalytic activity of the heterogeneous electrocatalysts for the electrochemical reaction, and wherein the electrocatalytic activity of the heterogeneous electrocatalyst for the electrochemical reaction is improved in comparison to the electrocatalytic activity of the conductive electrocatalytic substrate. In an embodiment disclosed herein or as an alternate or further embodiment, one or more thin films disclosed herein comprise, consist essentially of, or consists of metals, alloys, metal oxides, metal nitrides, metal sulfides, metal fluorides, or a combination thereof. In an embodiment disclosed herein or as an alternate or further embodiment, one of more thin films disclosed herein comprise, consist essentially of, or consists of one or more metal oxides selected from Al₂O₃, NH₄OSbW, Sb₂O₅, BaO, BaTiO₃, BaZrO₃, Al₆BeO₁₀, BeO, Bi₂O₃, Bi₂O₅, B₂O₃, CdO, CaO, Ce₂O₃, CeO₂, CrO, Cr₂O₃, CrO₂, CrO₃, CoO, Co₂O₃, Cu₂O₅Yb₂, Cu₂O, CuFe₂O₄, CuO, GaO, Ga₂O₃, GeO, GeO₂, Au₂O, Au₂O₃, HfO₂, In₂O, InO, In₂O₃, Ir₂O₃, IrO₂, Fe₃O₄, FeO, Fe₂O₃, PbO, PbO₂, Li₂O, Al₂MgO₄, MgO, Mn₃O₄, MnO, Mn₂O₃, MnO₂, Mn₂O₅, Mn₂O₇, Hg₂O, HgO, MoO₂, MoO₃, Mo₂O₅, NiFe₂O₄, NiO, Ni₂O₃, LiNbO₃, NaNbO₃, Nb₂O₃, Nb₂O₅, Os₂O₃, OsO₃, OsO₄, PdO, PdO₂, (C₆H₅) AsO, Pt₃O₄, PtO, Pt₂O₃, K₂O, Re₂O₇, ReO₄, Rh₂O₃, Rb₂O, RuO₂, RuO₄, SC₂O₃, Se₃O₄, Ag₂O, Na₂O, SrO, NaTaO₃, Ta₂O₃, Ta₂O₅, SiO₂, SnO, SnO₂, SrTiO₃, TiO, Ti₂O₃, TiO₂, WCl₂O₂, W₂O₃, WO₂, WO₃, W₂O₅, VOCl₂, VO, V₂O₃, VO₂, V₂O₅, Yb₂O₃, YBa₂Cu₃O₇, Y₂O₃, ZnO, ZrO₂, fluorine doped tin oxide, iron doped titanium oxide, WO₃ doped ZnO, Fe doped CeO₂, tin doped Fe₃O₄, and indium tin oxide. In an embodiment disclosed herein or as an alternate or further embodiment, one of more thin films disclosed herein comprise, consist essentially of, or consists of TiO₂. In an embodiment disclosed herein or as an alternate or further embodiment, a method disclosed herein uses 1 to 25 cycles of an atomic layer deposition process to deposit or layer one or more thin films onto a surface of the conductive electrocatalytic substrate. In an embodiment disclosed herein or as an alternate or further embodiment, a method disclosed herein uses 1 to 15 cycles of an atomic layer deposition process to deposit or layer a thin film of TiO₂ onto a surface of the conductive electrocatalytic substrate. In an embodiment disclosed herein or as an alternate or further embodiment, a method disclosed herein uses one or more thin films that are made from one or more precursors used in the atomic layer deposition process comprising, consisting essentially of, or consisting of aluminum tris(2,2,6,6-tetramethyl-3,5-heptanedionate), triisobutylaluminum, trimethylaluminum, tris(dimethylamido)aluminum(III), triphenylantimony(III), tris(dimethylamido)antimony(III), triphenylarsine, Triphenylarsine oxide, barium bis(2,2,6,6-tetramethyl-3,5-heptanedionate) hydrate, barium nitrate, Ba (C₉H₂₃N₃) ₂ [CₓH_{y}C(O)CHC(O)CₓH_{y}]₂ (x=3-4, y=2x+1), [Ba (C₅(CH₃)₅)₂].2(C₄H₈O), [Ba(C₅(C₃H₇)₃H₂)₂].2(C₄H₈O), bis (acetato-O) triphenylbismuth (V), triphenylbismuth, tris(2-methoxyphenyl)bismuthine, triisopropyl borate, triphenylborane, tris(pentafluorophenyl)borane, cadmium acetylacetonate, calcium bis(6,6,7,7,8,8,8,-heptafluoro-2,2-dimethyl-3,5-octanedionate), calcium bis(2,2,6,6-tetramethyl-3,5-heptanedionate), bis(cyclopentadienyl)chromium(II), bis(pentamethylcyclopentadienyl)chromium(II), chromium(III) tris(2,2,6,6-tetramethyl-3,5-heptanedionate), bis(cyclopentadienyl)cobalt(II), bis(pentamethylcyclopentadienyl)cobalt(II), copper bis(6,6,7,7,8,8,8-heptafluoro-2,2-dimethyl-3,5-octanedionate), copper bis(2,2,6,6-tetramethyl-3,5-heptanedionate), tris(dimethylamido)gallium(III), germanium(IV) fluoride, hexaethyldigermanium(IV), tetramethylgermanium, tributylgermanium hydride, triethylgermanium hydride, triphenylgermanium hydride, bis(tert-butylcyclopentadienyl)dimethylhafnium(IV), bis(trimethylsilyl)amidohafnium(IV) chloride, dimethylbis(cyclopentadienyl)hafnium(IV), tetrakis(diethylamido)hafnium(IV), tetrakis(dimethylamido)hafnium(IV), tetrakis(ethylmethylamido)hafnium(IV), [1,1′-bis(diphenylphosphino)ferrocene]tetracarbonylmolybdenum(0), bis(pentamethylcyclopentadienyl)iron(II), 1,1′-diethylferrocene, iron(0) pentacarbonyl, iron(III) tris(2,2,6,6-tetramethyl-3,5-heptanedionate), bis(cyclopentadienyl)magnesium(II), bis(pentamethylcyclopentadienyl)magnesium, Mg(C₆H₁₆N₂) [CₓH_{y}C(O)CHC(O)CₓH_{y}]₂ (x=3-4, y=2x+1), bis(pentamethylcyclopentadienyl)manganese(II), bis(tetramethylcyclopentadienyl)manganese(II), bromopentacarbonylmanganese(I), cyclopentadienylmanganese(I) tricarbonyl, ethylcyclopentadienylmanganese(I) tricarbonyl, manganese(0) carbonyl, (bicyclo[2.2.1]hepta-2,5-diene) tetracarbonylmolybdenum(0), bis(cyclopentadienyl)molybdenum(IV) dichloride, cyclopentadienylmolybdenum(II) tricarbonyl dimer, molybdenumhexacarbonyl, (propylcyclopentadienyl)molybdenum(I) tricarbonyl dimer, allyl(cyclopentadienyl)nickel(II), bis(cyclopentadienyl)nickel(II), bis(ethylcyclopentadienyl)nickel(II), nickel(II) bis(2,2,6,6-tetramethyl-3,5-heptanedionate), bis(cyclopentadienyl)niobium(IV) dichloride, trimethyl(methylcyclopentadienyl)platinum(IV), dirhenium decacarbonyl, (acetylacetonato) (1,5-cyclooctadiene)rhodium(I), (acetylacetonato) (1,5-cyclooctadiene)rhodium(I), bis(cyclopentadienyl)ruthenium(II), bis(ethylcyclopentadienyl)ruthenium(II), bis(pentamethylcyclopentadienyl)ruthenium(II), triruthenium dodecacarbonyl, Sr (C₉H₂₃N₃)₂ [CₓH_{y}C(O)CHC(O)CₓH_{y}]₂ (x=3-4, y=2x+1), pentakis(dimethylamino)tantalum(V), tantalum(V) ethoxide, tris(diethylamido) (tert-butylimido)tantalum(V), tris(ethylmethylamido) (tert-butylimido)tantalum(V), Ta (C₂H₅O)₄ [CₓH_{y}C(O)CHC(O)CₓHy]₂ (x=3-4, y=2x+1), bis[bis(trimethylsilyl)amino]tin(II), dibutyldiphenyltin, hexaphenylditin(IV), tetraallyltin, tetrakis(diethylamido)tin(IV), tetramethyltin, tetravinyltin, tin(II) acetylacetonate, trimethyl(phenylethynyl)tin, trimethyl(phenyl)tin, tetrakis (dimethylamido)titanium(IV) (TDMAT), tetrakis(ethylmethylamido)titanium(IV), titanium(IV) diisopropoxidebis(2,2,6,6-tetramethyl-3,5-heptanedionate), titanium tetrachloride, titanium(IV) isopropoxide, Ti(OC₃H₇)₂ [CₓH_{y}C(O)CHC(O)CₓH_{y}]₂ (x=3-4, y=2x+1), bis(butylcyclopentadienyl)tungsten(IV) diiodide, bis(tert-butylimino)bis(tert-butylamino)tungsten, bis(tert-butylimino)bis(dimethylamino)tungsten(VI), bis(cyclopentadienyl)tungsten(IV) dichloride, bis(cyclopentadienyl)tungsten(IV) dihydride, bis(isopropylcyclopentadienyl)tungsten(IV) dihydride, cyclopentadienyltungsten(II) tricarbonyl hydride, tetracarbonyl(1,5-cyclooctadiene)tungsten(0), triamminetungsten(IV) tricarbonyl, tungsten hexacarbonyl, bis(cyclopentadienyl)vanadium(II), bis(cyclopentadienyl)vanadium(II), vanadium(V) oxytriisopropoxide, bis(pentafluorophenyl)zinc, bis(2,2,6,6-tetramethyl-3,5-heptanedionato)zinc(II), diethylzinc, and diphenylzinc. In an embodiment disclosed herein or as an alternate or further embodiment, a method disclosed herein uses one or more thin films that are made from one or more precursors used in the atomic layer deposition process comprising, consisting essentially of, or consisting of tetrakis (dimethylamido)titanium(IV). In an embodiment disclosed herein or as an alternate or further embodiment, the conductive electrocatalytic substrate is at least 100 nm in thickness. In an embodiment disclosed herein or as an alternate or further embodiment, the conductive electrocatalytic substrate comprises, consists essentially of, or consists of a metal, alloy, metal oxide, metal nitride, metal sulfide, metal fluoride, or a combination thereof. In an embodiment disclosed herein or as an alternate or further embodiment, the conductive electrocatalytic substrate comprises, consists essentially of, or consists of a metal oxide selected from Al₂O₃, NH₄OSbW, Sb₂O₅, BaO, BaTiO₃, BaZrO₃, Al₆BeO₁₀, BeO, Bi₂O₃, Bi₂O₅, B₂O₃, CdO, CaO, Ce₂O₃, CeO₂, CrO, Cr₂O₃, CrO₂, CrO₃, CoO, Co₂O₃, Cu₂O₅Yb₂, Cu₂O, CuFe₂O₄, CuO, GaO, Ga₂O₃, GeO, GeO₂, Au₂O, Au₂O₃, HfO₂, In₂O, InO, In₂O₃, Ir₂O₃, IrO₂, Fe₃O₄, FeO, Fe₂O₃, PbO, PbO₂, Li₂O, Al₂MgO₄, MgO, Mn₃O₄, MnO, Mn₂O₃, MnO₂, Mn₂O₅, Mn₂O₇, Hg₂O, HgO, MoO₂, MoO₃, Mo₂O₅, NiFe₂O₄, NiO, Ni₂O₃, LiNbO₃, NaNbO₃, Nb₂O₃, Nb₂O₅, Os₂O₃, OsO₃, OsO₄, PdO, PdO₂, (C₆H₅) AsO, Pt₃O₄, PtO, Pt₂O₃, K₂O, Re₂O₇, ReO₄, Rh₂O₃, Rb₂O, RuO₂, RuO₄, Sc₂O₃, Se₃O₄, Ag₂O, Na₂O, SrO, NaTaO₃, Ta₂O₃, Ta₂O₅, SiO₂, SnO, SnO₂, SrTiO₃, TiO, Ti₂O₃, TiO₂, WCl₂O₂, W₂O₃, WO₂, WO₃, W₂O₅, VOCl₂, VO, V₂O₃, VO₂, V₂O₅, Yb₂O₃, YBa₂Cu₃O₇, Y₂O₃, ZnO, ZrO₂, fluorine doped tin oxide, iron doped titanium oxide, WO₃ doped ZnO, Fe doped CeO₂, tin doped Fe₃O₄, and indium tin oxide. In an embodiment disclosed herein or as an alternate or further embodiment, the conductive electrocatalytic substrate comprises, consists essentially of, or consists of IrO₂ or RuO₂. In an embodiment disclosed herein or as an alternate or further embodiment, the electrochemical reaction is selected from the group comprising, consisting essentially of, or consisting of the chlorine evolution reaction, the oxygen evolution reaction, the hydrogen evolution reaction, the carbon dioxide reduction reaction, the electrochemical water splitting reaction, the nitrogen reduction reaction and the oxygen reduction reaction. In an embodiment disclosed herein or as an alternate or further embodiment, the electrochemical reaction is the oxygen evolution reaction or the chlorine evolution reaction. In an embodiment disclosed herein or as an alternate or further embodiment, the electrochemical reaction the heterogeneous electrocatalyst exhibits a lower overpotential or improved specific activity for the chemical reaction than the conductive electrocatalytic substrate. In an embodiment disclosed herein or as an alternate or further embodiment, the heterogeneous electrocatalyst exhibits has a more favorable surface charge distribution for the chemical reaction than the conductive electrocatalytic substrate. In an embodiment disclosed herein or as an alternate or further embodiment, the disclosure provides for a heterogeneous electrocatalyst made by a method disclosed herein. In an embodiment disclosed herein or as an alternate or further embodiment, the disclosure provides for a heterogeneous electrocatalyst comprising a thin film of TiO₂ on a conductive electrocatalytic substrate of IrO₂, FTO, or RuO₂, wherein the thin film of TiO₂ is made from 1 to 15 cycles of an atomic layer deposition process. In one embodiment, the 1 to 15 cycles provides about 0.5 nm to 15 nm (e.g., deposition layer increasing the thickness) of film on the substrate. In an embodiment disclosed herein or as an alternate or further embodiment, the disclosure also provides for an electrode comprising, consisting essentially of, or consisting of a heterogeneous electrocatalyst disclosed herein. In an embodiment disclosed herein or as an alternate or further embodiment, the electrode is used to generate reactive chloride species in a wastewater treatment system.

### DESCRIPTION OF DRAWINGS

FIG. 1 demonstrates that a heterogeneous electrocatalyst made by layering TiO₂ onto IrO₂ using atomic layer deposition (ALD) resulted in a reduction in overpotential for the chlorine evolution reactions (CER) and oxygen evolution reactions (OER). The following overpotential reductions for CER and OER correlated with a change in catalyst surface charge density: Δη_{CER, 1 mA/cm}_{²}=97.4 mV, Δη_{GER, 10 mA/cm}_{²}=217.8 mV.

FIG. 2 presents a schematic representation of the Sabatier principle for heterogeneous electrocatalysts. Heterogeneous electrocatalysts act by forming bonds with reactants that stabilize transition states and destabilize intermediates. The perfect bond strength between the electrocatalyst and reactant will yield the optimal reactivity. A too strong or too weak bond will yield subpar reactivity. This concept, i.e., Sabatier principle, is demonstrated by the “volcano plot” where the x-axis is a measure of bonding and the y axis is a measure of catalytic activity.

FIG. 3 shows an example of a homogenous electrocatalyst system, where it is reasonably straightforward to tune the catalyst-reactant bond strength, by swapping and modifying ligands to be either more electron withdrawing or donating. Unfortunately, for heterogeneous electrocatalysts the tools to modify the electrocatalysts are not similarly available.

FIG. 4 provides a schematic of an atomic layer deposition process used herein for generating heterogeneous electrocatalysts. Also shown is the structure of tetrakis (dimethylamido)titanium(IV) (TDMAT), a titanium-based precursor used in the ALD process.

FIG. 5A-B presents (A) polarization curves for IrO₂ electrodes with various numbers of ALD cycles of TiO₂. Polarization was conducted in 5M NaCl, pH 2 under a chlorine atmosphere to ensure no significant oxygen evolution. (B) Example Tafel lines obtained by taking the logarithm of the current data in (A).

FIG. 6 demonstrates the average overpotentials at 0.1 mA/cm² as measured and calculated from at least 3 replicates of each IrO₂ electrode coated with various numbers of ALD cycles of TiO₂.

FIG. 7A-B provides impedance spectroscopy of RuO₂ as well as IrO₂ with various ALD cycle numbers of TiO₂. The resulting semi-circle was modeled as an Rs (CPE-Rp). The CPE-P term was between 0.9 and 1.0, indicating that the CPE-T term could reasonably be approximated as capacitance. (A) Each dot represents the capacitance measurement. The low point along the lines of dots represents the E_{PZC}. (B) E_{PZC} from points presented in plot (A) were utilized and graphed vs ALD cycles of TiO₂.

FIG. 8 presents representative polarization curves for IrO₂ electrodes coated with various numbers of ALD cycles of TiO₂. Polarization was conducted in 5 M NaCl at pH 2 to ensure no significant oxygen evolution. (Inset) example Tafel curves obtained from taking the logarithm of current density and extracting the linear portion of the resulting curve.

FIG. 9A-B presents the average exchange current densities (i₀) (A) and average overpotentials (B) of each IrO₂ based electrode coated with TiO₂ via cycles of ALD. Bare RuO₂ is shown as a red square for comparison. As thickness of TiO₂ increased beyond reasonably thick layers, the overpotential continued to increase considerably (see FIG. 11), likely due to the high resistivity of TiO₂. Overpotentials and exchange current densities are the average of at least 3 polarization curve replicates. Exchange current densities are obtained by fitting the polarization curve data to the Tafel equation and solving for the current density at the intersection between the log (current density) axis and the data fit line. Overpotentials are obtained by fitting the polarization curve data to the Tafel equation and solving for the applied potential less the Nernstian thermodynamic potential at zero current density.

FIG. 10 shows E_{PZC} of IrO₂ anodes coated with various ALD cycles of TiO₂. The red square denotes the E_{PZC} of RuO₂. E_{PZC} was calculated from electrochemical impedance spectroscopy (see FIG. 13). E_{PZC values represent the potential in any given solution at which an electrode has zero charge. E}_{PZC} is therefore a measure of the charge density of the surface species. In regards to metal oxides, E_{PZC} has a negative correlation with electronegativity of the metal. E_{PZC} is obtained by extracting the capacitance term from the circuit fit of the electrochemical impedance spectroscopy data for an electrode at several different applied potentials. The minimum capacitance value represents the E_{PZC} (see FIG. 12).

FIG. 11A-B presents the average exchange current densities (i₀) (A) and average overpotential at zero i₀ (B) of each IrO₂ based electrode coated with TiO₂ via cycles of ALD. Bare RuO₂ is shown as a red square for comparison. As thickness of TiO₂ increased beyond reasonably thick layers, the overpotential continued to increase, likely due to high resistivity. Overpotentials and exchange current densities are the average of at least 3 polarization curve replicates. These figures present the same data as FIG. 9, but are extended to 1000 ALD cycles.

FIG. 12 shows the electrochemical impedance spectroscopy of RuO₂ and IrO₂ coated with various ALD cycles of TiO₂ at 25 mV intervals. The resulting semi circles were modeled as Rs (CPE-Rp) circuits. The calculated capacitance values (dots) for each sample (set of dots) are shown. The minimum value of each curve represents the E_{PZC}. The magnitude of the capacitance values represents the surface area of the sample.

FIG. 13 presents E_{PZC} of IrO₂ anodes coated with various ALD cycles of TiO₂. E_{PZC} was calculated from electrochemical impedance spectroscopy (FIG. 12). This figure is the same as FIG. 10, except bulk TiO₂ (1000 ALD cycles) is also shown.

FIG. 14 shows the overpotential at 1 mA/cm² for the CER of TiO₂ deposited on RuO₂ using ever-increasing cycles. Standard CER conditions were 5M NaCl, pH 1 (HCl), 1 atm Cl₂, with 100% Faradaic Efficiency. Each dot represents a new catalyst that has a different number of atomic layer deposition cycles of TiO₂ on RuO₂ substrate. ALD cycles can be thought of as single atomic layers of TiOₓ.

FIG. 15 provides representative polarization curves for RuO₂ electrodes coated with various numbers of ALD cycles of TiO₂ for the OER.

FIG. 16 presents the specific activity (current density normalized to electrochemically active surface area) at a 350 mV overpotential in 1M H₂SO₄ under an oxygen atmosphere for the OER of TiO₂ deposited on RuO₂ using ever-increasing cycles. Each dot represents a new catalyst that has a different number of atomic layer deposition cycles of TiO₂. ALD cycles can be thought of as single atomic layers of TiOₓ.

FIG. 17 provides representative polarization curves for IrO₂ electrodes coated with various numbers of ALD cycles of TiO₂ for the CER. Polarization was conducted in 5 M NaCl at pH 2 under a chlorine gas atmosphere to ensure no significant oxygen evolution.

FIG. 18 shows the overpotential at 1 mA/cm² for the CER of TiO₂ deposited on IrO₂ using ever-increasing cycles. Standard CER conditions were 5M NaCl, pH 2 (HCl), 1 atm Cl₂, with 100% Faradaic Efficiency. Each dot represents a new catalyst that has a different number of atomic layer deposition cycles of TiO₂ on IrO₂ substrate. ALD cycles can be thought of as single atomic layers of TiOₓ. Deposition of TiO₂ on IrO₂ lead to a ˜30 mV reduction in overpotential for the CER at 1 mA/cm². For the best overpotential η_{IrO}_{ₓ}_{/TiO}_{₂}_{,CER}=97.3 mV.

FIG. 19 provides representative polarization curves for IrO₂ electrodes coated with various numbers of ALD cycles of TiO₂ for the OER.

FIG. 20 presents the specific activity at a 350 mV overpotential in 1M H₂SO₄ under 1 atm of oxygen for the OER of TiO₂ deposited on IrO₂ using ever-increasing cycles. Each dot represents a new catalyst that has a different number of atomic layer deposition cycles of TiO₂. ALD cycles can be thought of as single atomic layers of TiOₓ.

FIG. 21 shows the overpotential at 1 mA/cm² for the CER of TiO₂ deposited on FTO using ever-increasing cycles. Standard CER conditions were 5M NaCl, pH 1 (HCl), 1 atm Cl₂, with 100% Faradaic Efficiency. Each dot represents a new catalyst that has a different number of atomic layer deposition cycles of TiO₂ on FTO substrate. ALD cycles can be thought of as single atomic layers of TiOₓ. Deposition of TiO₂ on FTO lead to a ˜140 mV reduction in overpotential for the CER at 1 mA/cm². The best overpotential for this catalyst is reduced to η_{FTO/TiO,CER}=142.4 mV.

FIG. 22 provides representative polarization curves for FTO electrodes coated with various numbers of ALD cycles of TiO₂ for the OER.

FIG. 23 presents the specific activity at a 350 mV overpotential in 1M H₂SO₄ for the OER of TiO₂ deposited on FTO under an oxygen atmosphere using ever-increasing cycles. Each dot represents a new catalyst that has a different number of atomic layer deposition cycles of TiO₂. ALD cycles can be thought of as single atomic layers of TiOₓ.

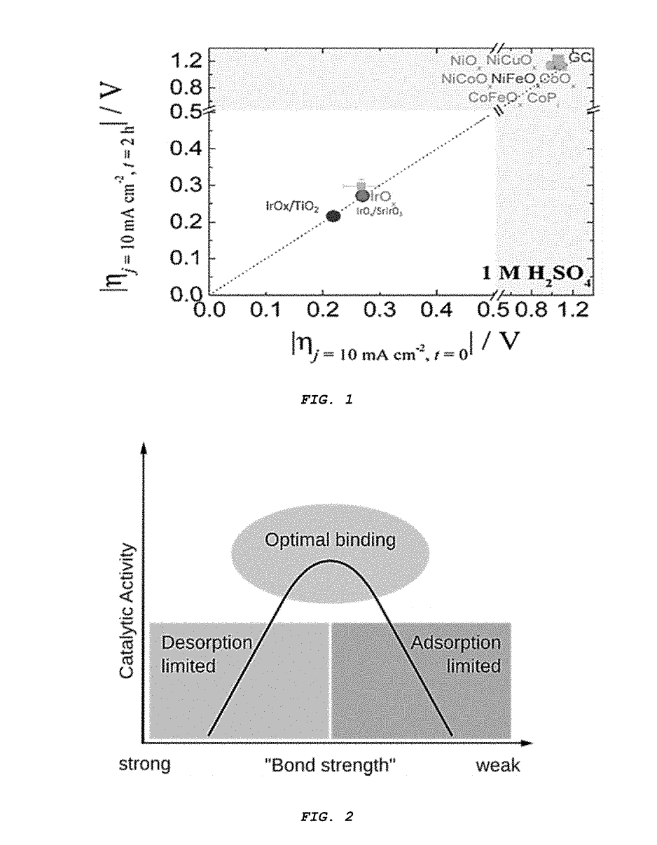

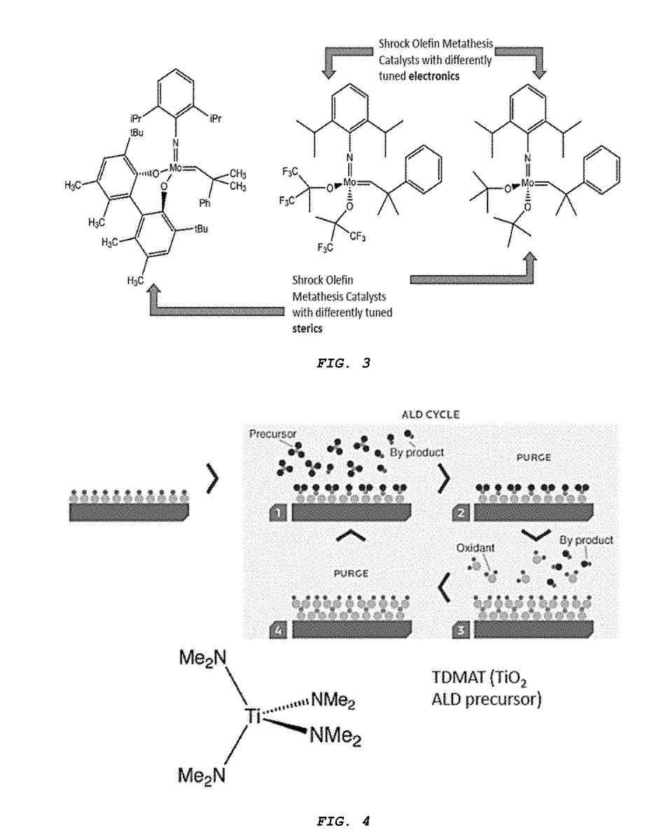

### DETAILED DESCRIPTION

As used herein and in the appended claims, the singular forms “a,” “an,” and “the” include plural referents unless the context clearly dictates otherwise. Thus, for example, reference to “a heterogeneous electrocatalyst” includes a plurality of such heterogeneous electrocatalysts and reference to “the thin film” includes reference to one or more thin films and equivalents thereof known to those skilled in the art, and so forth.

Also, the use of “or” means “and/or” unless stated otherwise. Similarly, “comprise,” “comprises,” “comprising” “include,” “includes,” and “including” are interchangeable and not intended to be limiting.

It is to be further understood that where descriptions of various embodiments use the term “comprising,” those skilled in the art would understand that in some specific instances, an embodiment can be alternatively described using language “consisting essentially of” or “consisting of.”

Unless defined otherwise, all technical and scientific terms used herein have the same meaning as commonly understood to one of ordinary skill in the art to which this disclosure belongs. Although many methods and reagents are similar or equivalent to those described herein, the exemplary methods and materials are disclosed herein.

All publications mentioned herein are incorporated herein by reference in full for the purpose of describing and disclosing the methodologies, which might be used in connection with the description herein. Moreover, for terms expressly defined in this disclosure, the definition of the term as expressly provided in this disclosure will control in all respects, even if the term has been given a different meaning in a publication, dictionary, treatise, and the like.

A “conductive material” as used herein refers to a material that allows the flow of an electrical current in one or more directions. Materials made of metal are common electrical conductors. Electrical current is generated by the flow of negatively charged electrons, positively charged holes, and positive or negative ions in some cases. Examples of conductive materials, include but are not limited to, metals, alloys, metal containing compounds, graphite, and conductive polymers. Examples of good conducting metals include but are not limited to, silver, copper, gold, aluminum, molybdenum, zinc, lithium, tungsten, brass, nickel, iron, palladium, platinum, and tin.

A “semiconductive material” as used herein refers to material has an electrical conductivity value falling between that of a conductor, such as copper, and an insulator, such as glass. The resistance of a semiconductive material decreases as the temperature of the semiconductive material increases, which is behavior opposite to that of a metal. The conducting properties of semiconductive material may be altered in useful ways by the deliberate, controlled introduction of impurities (“doping”) into the crystal structure. Where two differently-doped regions exist in the same crystal, a semiconductor junction is created. The behavior of charge carriers which include electrons, ions and electron holes at these junctions is the basis of diodes, transistors and all modern electronics. Semiconductor devices can display a range of useful properties such as passing current more easily in one direction than the other, showing variable resistance, and sensitivity to light or heat. Because the electrical properties of a semiconductor material can be modified by doping, or by the application of electrical fields or light, devices made from semiconductors can be used for amplification, switching, and energy conversion. Examples of semiconductive materials include, but are not limited to, group 14 elements (e.g., C, Si, Ge); binary compounds between group 13 and 15 elements (e.g., AlSb, GaAs, GaN, GaP, InN, InP); binary compounds between groups 12 and 16 elements (e.g., CdS, ZnO, ZnS, ZnTe); binary compounds between group 14 and 16 elements (e.g., PbSe, PbS, SnS, SnTe); and binary compounds between different group 14 elements (e.g., SiC) ternary semiconductor alloys (e.g., Al/Ga/As, In/Ga/As, In/Ga/P, Ga/As/N, Ga/As/P, In/Ga/N); and semiconductive oxides (e.g., TiO₂, Cu₂O, CuO, Bi₂O₃, ZnO, SnO₂, BaTiO₃, SrTiO₃).

A “superconductive material” as used herein refers to metals, ceramics, organic materials, or heavily doped semiconductors that conduct electricity without resistance. Superconducting materials can transport electrons with no resistance, and hence release no heat, sound, or other energy forms. Superconductivity occurs at a specific material's critical temperature (T_{c}). As temperature decreases, a superconducting material's resistance gradually decreases until it reaches critical temperature. At this point resistance drops off, often to zero. Examples of superconductive materials include, but are not limited to, type II alloys (e.g., Hg/Ba/Ca/Cu/O, Hg/Ti/Ba/Ca/Cu/O, Hg/Ba/Ca/Cu/O, Ti/Ba/Ca/Cu/O, Bi/Sr/Ca/Cu/O).

An “electrocatalyst” as used herein refers to a catalyst that participates in an electrochemical reaction, and which modifies or increases the rate of the electrochemical reaction without being consumed in the process. An electrocatalyst can be heterogeneous such as a metal oxide surface, or homogeneous like a coordination complex. The electrocatalyst assists in transferring electrons between the electrode and reactants, and/or facilitates an intermediate chemical transformation described by an overall half-reaction.

A “heterogeneous electrocatalyst” as used herein refers to a catalyst that participates in electrochemical reactions and which is in a separate phase from the reactants and/or products. For example, the reactants and products may be in a fluid phase, while the heterogeneous electrocatalyst is in a solid phase.

A “homogenous electrocatalyst” as used herein refers to a catalyst that participates in electrochemical reactions and which is in the same phase as the reactants and/or products.

An “electrochemical reaction” as used herein refers to a process either caused or accompanied by the passage of an electrons or an electric current and involving in most cases the transfer of electrons between two substances. The energy of an electric current can then be used to bring about many chemical reactions that do not occur spontaneously. Examples of “electrochemical reactions” include the chlorine evolution reaction, the oxygen evolution reaction, the hydrogen evolution reaction, the carbon dioxide reduction reaction, the electrochemical water splitting reaction, the nitrogen reduction reaction, and the oxygen reduction reaction.

A “thin film” as used herein refers to one or more layers of a conductive material and/or semiconductive material as defined herein that has been applied or deposited onto the surface of another conductive material, semiconductive and/or superconductive material. For purposes herein, the composition of the thin film is different from the composition of the conductive material, semiconductive and/or superconductive material that thin film is in direct contact with. For example, a thin film of TiO₂ deposited or applied to an IrO₂ substrate. Universally, the “thin film” is applied, deposited, or layered on top of the surface of another conductive material, semiconductive material and/or superconductive material. Typically, a chemical vapor deposition (CVD)-based process or an atomic layer deposition (ALD)-based process is used to apply, or deposit a thin film on top of the surface of another conductive material, semiconductive material, or superconductive material. In a certain embodiment, a “thin film” as used herein refers to a layer of conductive and/or semiconductive material which has a thickness of <50 nm, <25 nm, <10 nm, <5 nm, <1 nm, <9 Å, <8 Å, <7 Å, <6 Å, <5 Å, <4 Å, <3 Å, <2 Å, <1 Å, or <0.5 Å. In a particular embodiment, the ‘thin film’ is a layer of conductive material that has a thickness of 0.1 Å, 0.2 Å, 0.3 Å, 0.4 Å, 0.5 Å, 0.6 Å, 0.7 Å, 0.8 Å, 0.9 Å, 1 Å, 1.1 Å, 1.2 Å, 1.3 Å, 1.4 Å, 1.5 Å, 1.6 Å, 1.7 Å, 1.8 Å, 1.9 Å, 2 Å, 2.1 Å, 2.2 Å, 2.3 Å, 2.4 Å, 2.5 Å, 2.6 Å, 2.7 Å, 2.8 Å, 2.9 Å, 3 Å, 3.1 Å, 3.2 Å, 3.3 Å, 3.4 Å, 3.5 Å, 3.6 Å, 3.7 Å, 3.8 Å, 3.9 Å, 4 Å, 4.1 Å, 4.2 Å, 4.3 Å, 4.4 Å, 4.5 Å, 4.6 Å, 4.7 Å, 4.8 Å, 4.9 Å, 5 Å, 5.1 Å, 5.2 Å, 5.3 Å, 5.4 Å, 5.5 Å, 5.6 Å, 5.7 Å, 5.8 Å, 5.9 Å, 6 Å, 6.1 Å, 6.2 Å, 6.3 Å, 6.4 Å, 6.5 Å, 6.6 Å, 6.7 Å, 6.8 Å, 6.9 Å, 7 Å, 7.1 Å, 7.2 Å, 7.3 Å, 7.4 Å, 7.5 Å, 7.6 Å, 7.7 Å, 7.8 Å, 7.9 Å, 8 Å, 8.1 Å, 8.2 Å, 8.3 Å, 8.4 Å, 8.5 Å, 8.6 Å, 8.7 Å, 8.8 Å, 8.9 Å, 9 Å, 9.1 Å, 9.2 Å, 9.3 Å, 9.4 Å, 9.5 Å, 9.6 Å, 9.7 Å, 9.8 Å, 9.9 Å, 1 nm, 2 nm, 3 nm, 4 nm, 5 nm, 6 nm, 7 nm, 8 nm, 9 nm, 10 nm, 12 nm, 14 nm, 15 nm, 16 nm, 18 nm, 20 nm, 25 nm, 30 nm, 35 nm, 40 nm, 45 nm, 50 nm, or a range including or between any two of the foregoing numbers. In regards to an ALD-based process, the thickness of the ‘thin film’ is directly controlled based upon the number of cycles used in the ALD-based process. Thus, in another embodiment, a ‘thin film’ as used herein refers to a layer of conductive material and/or semiconductive material which has a thickness resulting from using an ALD process with 1 to 1000 cycles, 1 to 500 cycles, 1 to 100 cycles, 1 to 90 cycles, 1 to 80 cycles, 1 to 70 cycles, 1 to 60 cycles, 1 to 55 cycles, 1 to 50 cycles, 1 to 45 cycles, 1 to 40 cycles, 1 to 35 cycles, 1 to 30 cycles, 1 to 25 cycles, 1 to 24 cycles, 1 to 23 cycles, 1 to 22 cycles, 1 to 21 cycles, 1 to 20 cycles, 1 to 19 cycles, 1 to 18, cycles, 1 to 17 cycles, 1 to 16 cycles, 1 to 15 cycles, 1 to 14 cycles, 1 to 13 cycles, 1 to 12 cycles, 1 to 11 cycles, 1 to 10 cycles, 1 to 9 cycles, 1 to 7 cycles, 1 to 6 cycles or 1 to 5 cycles. In yet another embodiment, a ‘thin film’ as used herein refers to a layer of conductive material and/or semiconductive material which has a thickness resulting from using an ALD process with 1 cycle, 2 cycles, 3 cycles, 4 cycles, 5 cycles, 6 cycles, 7 cycles, 8 cycles, 9 cycles, 10 cycles, 11 cycles, 12 cycles, 13 cycles, 14 cycles, 15 cycles, 16 cycles, 17 cycles, 18 cycles, 19 cycles, 20 cycles, 21 cycles, 22 cycles, 23 cycles, 24 cycles, 25 cycles, 30 cycles, 35 cycles, 40 cycles, 45 cycles, 50 cycles, 55 cycles, 60 cycles, 70 cycles, 80 cycles, 90 cycles, 100 cycles, 500 cycles, 1000 cycles, or any range between any two of the foregoing cycle numbers.

A “conductive electrocatalytic substrate” as used herein refers to substrate that is comprised of one or more conductive materials, semiconductive materials and/or superconductive materials as defined herein that can be used as a catalyst in an electrochemical reaction. The conductive electrocatalytic substrate is not limited to having any specific shape or having any specific dimension (e.g., thickness). Accordingly, the conductive electrocatalytic substrate can have any shape and any suitable dimension. In a particular embodiment, the substrate is 100 nm, ≧1 μm, ≧10 μm, 100 μm or 1 mm in thickness. In a particular embodiment, the conductive electrocatalytic substrate is a component of an electrode. In an alternate embodiment, an electrode comprises the conductive electrocatalytic substrate.

Electrocatalysts are used both to speed up electrode reactions and to enable them to occur close to their thermodynamically predicted potentials. In electrochemical power supplies such as fuel cells, the incorporation of electrocatalysts into the electrode structure enables the fuel cell to operate near its theoretically expected potential even when appreciable current is drawn from the cell. The electrocatalyst is said to reduce the overvoltage for the electrode reaction. A related example is the water electrolysis cell; electrocatalysts are important here to lower the minimum voltage necessary for electrolysis to occur, and to keep it low as the rate of electrolysis at the electrodes is increased—this will permit high efficiency of operation.

Unlike in homogenous catalysis where electron donating/withdrawing or sterically hindering ligands can be used to define a perfect catalytic active site, progress in the field of heterogeneous electrocatalysis has been relatively attenuated due to limited tools for crafting active sites. For heterogeneous catalysts, optimizing bond strength to a precursor is a difficult task. Previous studies have used dopants, vacancies, mixed oxides, topography induced strain, and ligand addition to alter electronics, mainly by sterics. Full tunability, however, has proven very difficult. In order to design optimal active sites, more tools are needed. The methods described herein have been shown to be useful for tuning surface electronics. In particular, to tune the surface electronics and corresponding activity of heterogeneous electrocatalysts for the industrially and environmentally important electrochemical reactions (e.g., Chlorine Evolution Reaction (CER) and the Oxygen Evolution Reaction (OER)).

The CER is fundamentally important for a myriad of industrial processes. Global chlorine production is currently an 88.5-billion-dollar industry, with 40-50% of the production cost being due to the cost for electricity. Additionally, chlorine evolution electrocatalysts have shown great promise for treating and recycling wastewater in the developing world.

The most active known catalyst for the CER is RuO₂ which operates at near zero overpotential in concentrated brine for 1 mA/cm², however, RuO₂ is seldom used industrially due to low stability. Instead, IrO₂ and RuO₂/IrO₂ mixed metal oxide catalysts are preferred even though they have diminished activity (overpotentials >50 mV in concentrated brine for 1 mA²) but much better stability. In highly corrosive environments like wastewater treatment, IrO₂ is occasionally coated with TiO₂ to enhance stability (overpotential >>50 mV in concentrated brine for 1 mA/cm²).

Development of catalysts is important for storing energy and creating commodity chemicals. Catalysts act to reduce a chemical reaction's activation energy requirements by destabilizing intermediates and stabilizing transition states. On catalysts, reactant binding sites (active sites) provide the specific requirements for optimal binding of reactants—neither too tightly, preventing release of products or initiation of catalysis, nor too loosely, preventing conversion to products. Altering the activity of an electrocatalyst is therefore possible by tailoring the active site charge density, which alters how well the catalyst binds to reaction intermediates. In homogenous electrocatalysis, designer electron donating/withdrawing ligands or sterically hindering ligands can be used to tune catalytic activity by optimizing the charge density of active sites on metal centers.

The strategies employed in homogenous catalysis for controlling the charge density at the active site often fail for heterogeneous catalysts, however. For example, ligands tend to be unstable on the surface of heterogeneous catalysts, and may block already coordinately saturated active sites. Unlike in homogenous catalysis where the binding environment primarily controls the active site charge density, in heterogeneous electrocatalysis the applied potential also affects the charge density at the binding site, further complicating one's ability to predictably alter the active site charge density. Previous studies have used dopants, vacancies, mixed oxides, topographically induced strain, and in special cases ligand addition to alter the charge density of surface species on heterogeneous catalysts with some success. However, complete tunability of surface charge density on heterogeneous catalysts has not been shown and additional tools are therefore needed to improve electrocatalytic efficiencies.

Reported herein are methods that have been demonstrated as providing an effective means for tuning the catalytic parameters on heterogeneous electrocatalysts in a way similar to ligand addition in homogenous electrocatalysts (e.g., using an electron rich ligand on an electron poor metal to form an intermediate electron density at the binding site). In a particular embodiment, the methods of the disclosure provide a step of layering or applying one or more materials (e.g., electrocatalytic materials) to another different material (e.g., a different electrocatalytic material) using atomic layer deposition, wherein the thickness of the layered or applied material can be tunably controlled based upon the number of ALD cycles. The general principal of this catalyst tuning process is that it is possible to create surfaces with designer and predictable properties for catalysis. This is achieved by layering multiple conductive materials that are sufficiently thin such that the overlying film can electronically “feel” the underlying film. When a very thin layer is stacked on top of another layer, the surface becomes an electronic average of the two materials. That average can be tuned by tuning the thickness of the overlying materials. For example, a single atomic layer of an overlying materials will look a lot more like the underlying material than 100 atomic layers of the overlying material will look.

As shown herein, the methods of the disclosure were utilized to produce a TiO₂ coated IrO₂ electrocatalyst that exhibited improved catalytic properties for the chlorine evolution reaction (CER). The CER accounts for greater than 2% of global energy demand and further has shown promise for treating and recycling wastewater, especially in the non-developed world where a sewer system is generally lacking.

The methods provided herein, provide a new means by which heterogeneous electrocatalysts could be designed and developed. In a particular embodiment, the methods disclosed herein allow for the deposition of one or more thin layers of a conductive material on top of another conductive material or substrate so as to afford a new material that has electronic properties that are intermediate between the two (or more) conductive materials. While not beholden to the specific examples presented herein, it is clear that methods of disclosure can be used to design heterogeneous electrocatalysts that have improved catalytic activities for the oxygen evolution reaction, and the chlorine evolution reaction. Additionally, the methods of the disclosure are directed to a platform technology, whereby the methods can be similarly applied to improve the catalytic activities of electrocatalysts in other types of reactions, including but not limited to, the chlorine evolution reaction, the oxygen evolution reaction, the hydrogen evolution reaction, the carbon dioxide reduction reaction, the electrochemical water splitting reaction, the nitrogen reduction reaction and the oxygen reduction reaction. Thus, it is possible to improve the electrocatalytic activities of common non-precious metals by tuning these metals using the methods disclosed herein to have electronic properties similar to that of precious or rare earth metals. The methods of the disclosure, therefore, could realize substantial cost savings for industry in regards of cost for mineral resources, production, and energy.

Previous technologies exist for tuning electrocatalyst electronic properties, for example doping, creating vacancies, mixing oxides, and adding ligands. These technologies, however, are not sufficient to fully tune catalyst electronics. For example, heretofore there was no good way to tune IrO₂ to a sufficient level to improve the operating overpotential of the material in the chlorine evolution reaction. Additionally, the methods disclosed herein allow for rational designing catalytic systems for particular reactions. Previous technologies, like doping, heavily relied on trial and error to tune the surface electronics. Using the methods disclosed herein, it is now possible to evaluate materials based upon their associated electronic properties, properties such as electronic structure, polarity in forming bonds, bond strength, and electronegativities of the elements making up the material, and then layering another material which has complementary or different properties in thin layers on top of the first material to afford a new material that has electronic properties that are somewhere between the two materials, which can be adjusted if desired, based upon the number of cycles in the layering process. Thus, the methods of the disclosure now make it possible to create custom electrocatalytic materials that have more desirable electronic properties based upon combining the electronic properties of known materials to make new electrocatalytic materials.

The data presented herein indicate that adding various layers of a metal oxide with a more electron poor metal and more electron rich oxygen on top of a metal oxide with a less electron poor metal and less electron rich oxygen can tune the surface charge density and the catalytic parameters. Furthermore, the data show that when the charge density is matched to that of a better catalyst, the catalytic parameters also match as predicted by the Sabatier principal. Therefore, the methods of the disclosure represent a new means for improving the performance of heterogeneous electrocatalysts by tuning an active surface species' charge density by overcoating with an appropriate material or mix of materials. Furthermore, the methods of the disclosure provide a pathway to enhance the catalytic activity of earth abundant electrocatalysts for important reactions that was not previously available due to a dearth of means to tune the activity of heterogeneous electrocatalysts. By looking at parameters that dictate the electron concentration of the surface (i.e., heat of formation, electron affinity, potential of zero charge, etc.) of the best-known catalyst (RuO₂), a series of new catalysts for the chlorine and the oxygen evolution reactions were generated. Based up testing, some of these newly created catalysts exhibited catalytic properties which exceeded that of the ‘best’ known catalysts for the OER and CER reactions. In particular, conductive materials were chosen such that the surface charge concentration properties of the composite material were similar to that of RuO₂ (i.e., Ti has an electron affinity of −8 eV while Ir has an electron affinity of −150 eV and Ru has an electron affinity of −101 eV). It was found that layering TiO₂ on top of IrO₂ provided for a composite material that had similar surface charge properties to RuO₂. It should be noted, however, that RuO₂ while having favorable surface charge properties for the OER, suffers from low stability. Thus, the above composite material of TiO₂ and IrO₂ exhibits favorable surface charge properties as RuO₂, but without the stabilities concerns. Using the methods disclosed herein, FTC), IrO₂, and RuO₂ were coated with a thin layer of TiO₂ so as to improve the specific catalytic activities of each catalyst. In particular, the methods disclosed herein allowed for the manufacture of a catalyst that exhibited the highest intrinsic activity for the OER known in the art. Moreover, all three under layers showed order of magnitude increases in specific activity for both the chlorine evolution reaction and the oxygen evolution reaction for a given overlying thickness of TiO₂. These materials showed a predictable “volcano” trend where activities initially increased with TiO₂ layers then peaked and decreased again. Accordingly, the methods of the disclosure represent a platform technology that can be broadly applied to many heterogeneous electrocatalyst systems, such as designing and fabricating new heterogeneous electrocatalysts for all types of reactions from energy storage in batteries or fuels to industrial commodity chemical production and more.

In a particular embodiment, the disclosure provides for applying a thin film of a conductive material using one or more cycles of atomic layer deposition to a surface of another different conductive material or substrate. Atomic layer deposition (ALD) is a thin film deposition technique that is based on the sequential use of a gas phase chemical process (see FIG. 4). ALD is considered a subclass of chemical vapor deposition. The majority of ALD reactions use two chemicals, typically called precursors. These precursors react with the surface of a material one at a time in a sequential, self-limiting, manner. Through the repeated exposure to separate precursors, a thin film is slowly deposited. In contrast to chemical vapor deposition, the precursors are never present simultaneously in the reactor, but they are inserted as a series of sequential, non-overlapping pulses. In each of these pulses the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction. By varying the number of cycles, it is possible to grow materials uniformly and with high precision on arbitrarily complex and large substrates. ALD produces very thin, conformal films with control of the thickness and composition of the films possible at the atomic level.

In a prototypical ALD process, a substrate is exposed to two reactants A and B in a sequential, non-overlapping way. In contrast to other techniques such as chemical vapor deposition (CVD), where thin film growth proceeds on a steady-state fashion, in ALD each reactant reacts with the surface in a self-limited way: the reactant molecules can react only with a finite number of reactive sites on the surface. Once all those sites have been consumed in the reactor, the growth stops. The remaining reactant molecules are flushed away and only then reactant B is inserted into the reactor. By alternating exposures of A and B, a thin film is deposited. Consequently, when describing an ALD process one refers to both dose times (the time a surface is being exposed to a precursor) and purge times (the time left in between doses for the precursor to evacuate the chamber) for each precursor. The dose-purge-dose-purge sequence of a binary ALD process constitutes an ALD cycle. Also, rather than using the concept of growth rate, ALD processes are described in terms of their growth per cycle.

In ALD, enough time must be allowed in each reaction step so that a full adsorption density can be achieved. When this happens, the process has reached saturation. This time will depend on two key factors: the precursor pressure, and the sticking probability. Therefore, the rate of adsorption per unit of surface area can be expressed as:

R_{abs}=S*F

Where R is the rate of adsorption, S is the sticking probability, and F is the incident molar flux. However, a key characteristic of ALD is the S will change with time, as more molecules have reacted with the surface this sticking probability will become smaller until reaching a value of zero once saturation is reached.

While the reaction mechanisms are strongly dependent on the particular ALD process, there are hundreds of ALD processes described in the literature to deposit oxide, metals, nitrides, sulfides, chalcogenides, and fluoride materials. The right selection of precursors is very important in order to obtain the desired material. Initially CVD precursors include metal hydrides and halides but today a large array of metal organic compounds are used that include metal alkoxides, metal alkyls, metal diketonites, metal amidinates, metal carbonyls and others. It is important that precursors are volatile but thermally stable so that they do not decompose during vaporization, and are preferably soluble in an inert solvent or liquid at room temperature. Furthermore, they must have preferential reactivity towards the substrate and the growing film. It is also important that ALD precursors have self-limiting reactivity with the substrate and the film surface. For most precursors, only one element is contributed to the deposited film, with the rest of the molecules vaporized during the process. Certain compounds can contribute more than one element and bring down the number of reactants needed for a specific process. Precursors for ALD are commercially available from a variety of vendors (e.g., Sigma Aldrich Co., St. Louis Mo.; and Strem Chemicals Inc., Newburyport, Mass.). Examples of ALD precursors include, but are not limited to, aluminum tris(2,2,6,6-tetramethyl-3,5-heptanedionate), triisobutylaluminum, trimethylaluminum, tris(dimethylamido)aluminum(III), triphenylantimony(III), tris(dimethylamido)antimony(III), triphenylarsine, Triphenylarsine oxide, barium bis(2,2,6,6-tetramethyl-3,5-heptanedionate) hydrate, barium nitrate, Ba (C₉H₂₃N₃)₂ [CₓH_{y}C(O)CHC(O)CₓH_{y}]₂ (x=3-4, y=2x+1), [Ba (C₅(CH₃)₅)₂].2(C₄H₈O), [Ba(C₅(C₃H₇)₃H₂)₂].2(C₄H₈O), bis (acetato-O) triphenylbismuth (V) , triphenylbismuth, tris(2-methoxyphenyl)bismuthine, triisopropyl borate, triphenylborane, tris(pentafluorophenyl)borane, cadmium acetylacetonate, calcium bis(6,6,7,7,8,8,8,-heptafluoro-2,2-dimethyl-3,5-octanedionate), calcium bis(2,2,6,6-tetramethyl-3,5-heptanedionate), bis(cyclopentadienyl)chromium(II), bis(pentamethylcyclopentadienyl)chromium(II), chromium(III) tris(2,2,6,6-tetramethyl-3,5-heptanedionate), bis(cyclopentadienyl)cobalt(II), bis(pentamethylcyclopentadienyl)cobalt(II), copper bis(6,6,7,7,8,8,8-heptafluoro-2,2-dimethyl-3,5-octanedionate), copper bis(2,2,6,6-tetramethyl-3,5-heptanedionate), tris(dimethylamido)gallium(III), germanium(IV) fluoride, hexaethyldigermanium(IV), tetramethylgermanium, tributylgermanium hydride, triethylgermanium hydride, triphenylgermanium hydride, bis(tert-butylcyclopentadienyl)dimethylhafnium(IV), bis(trimethylsilyl)amidohafnium(IV) chloride, dimethylbis(cyclopentadienyl)hafnium(IV), tetrakis(diethylamido)hafnium(IV), tetrakis(dimethylamido)hafnium(IV), tetrakis(ethylmethylamido)hafnium(IV), [1,1′-bis(diphenylphosphino)ferrocene]tetracarbonylmolybdenum(0), bis(pentamethylcyclopentadienyl)iron(II), 1,1′-diethylferrocene, iron(0) pentacarbonyl, iron(III) tris(2,2,6,6-tetramethyl-3,5-heptanedionate), bis(cyclopentadienyl)magnesium(II), bis(pentamethylcyclopentadienyl)magnesium, Mg(C₆H₁₆N₂) [CₓH_{y}C(O)CHC(O)CₓH_{y}]₂ (x=3-4, y=2x+1), bis(pentamethylcyclopentadienyl)manganese(II), bis(tetramethylcyclopentadienyl)manganese(II), bromopentacarbonylmanganese(I), cyclopentadienylmanganese(I) tricarbonyl, ethylcyclopentadienylmanganese(I) tricarbonyl, manganese(0) carbonyl, (bicyclo[2.2.1]hepta-2,5-diene) tetracarbonylmolybdenum(0), bis(cyclopentadienyl)molybdenum(IV) dichloride, cyclopentadienylmolybdenum(II) tricarbonyl dimer, molybdenumhexacarbonyl, (propylcyclopentadienyl)molybdenum(I) tricarbonyl dimer, allyl(cyclopentadienyl)nickel(II), bis(cyclopentadienyl)nickel(II), bis(ethylcyclopentadienyl)nickel(II), nickel(II) bis(2,2,6,6-tetramethyl-3,5-heptanedionate), bis(cyclopentadienyl)niobium(IV) dichloride, trimethyl(methylcyclopentadienyl)platinum(IV), dirhenium decacarbonyl, (acetylacetonato) (1,5-cyclooctadiene)rhodium(I), (acetylacetonato) (1,5-cyclooctadiene)rhodium(I), bis(cyclopentadienyl)ruthenium(II), bis(ethylcyclopentadienyl)ruthenium(II), bis(pentamethylcyclopentadienyl)ruthenium(II), triruthenium dodecacarbonyl, Sr(C₉H₂₃N₃)₂[CₓH_{y}C(O)CHC(O)CₓH_{y}]₂ (x=3-4, y=2x+1), pentakis(dimethylamino)tantalum(V), tantalum(V) ethoxide, tris(diethylamido) (tert-butylimido)tantalum(V), tris(ethylmethylamido) (tert-butylimido)tantalum(V), Ta(C₂H₅O)₄ [CₓH_{y}C(O)CHC(O)CₓH_{y}]₂ (x=3-4, y=2x+1), bis[bis(trimethylsilyl)amino]tin(II), dibutyldiphenyltin, hexaphenylditin(IV), tetraallyltin, tetrakis(diethylamido)tin(IV), tetramethyltin, tetravinyltin, tin(II) acetylacetonate, trimethyl(phenylethynyl)tin, trimethyl(phenyl)tin, tetrakis (dimethylamido)titanium(IV) (TDMAT), tetrakis(ethylmethylamido)titanium(IV), titanium(IV) diisopropoxidebis(2,2,6,6-tetramethyl-3,5-heptanedionate), titanium tetrachloride, titanium(IV) isopropoxide, Ti(OC₃H₇)₂ [CₓH_{y}C(O)CHC(O)CₓH_{y}]₂ (x=3-4, y=2x+1), bis(butylcyclopentadienyl)tungsten(IV) diiodide, bis(tert-butylimino)bis(tert-butylamino)tungsten, bis(tert-butylimino)bis(dimethylamino)tungsten(VI), bis(cyclopentadienyl)tungsten(IV) dichloride, bis(cyclopentadienyl)tungsten(IV) dihydride, bis(isopropylcyclopentadienyl)tungsten(IV) dihydride, cyclopentadienyltungsten(II) tricarbonyl hydride, tetracarbonyl(1,5-cyclooctadiene)tungsten(0), triamminetungsten(IV) tricarbonyl, tungsten hexacarbonyl, bis(cyclopentadienyl)vanadium(II), bis(cyclopentadienyl)vanadium(II), vanadium(V) oxytriisopropoxide, bis(pentafluorophenyl)zinc, bis(2,2,6,6-tetramethyl-3,5-heptanedionato)zinc(II), diethylzinc, and diphenylzinc.

In a certain embodiment, the conductive catalytic materials or electrocatalysts of the disclosure comprises metals, metal sufides, metal nitrides, metal fluorides, metal oxides, alloys, or any combination of the foregoing. Moreover, any of the foregoing may further comprise dopants, e.g., iridium doped iron oxide, molybdenum doped iron oxide, niobium doped iron oxide, and fluorine doped tin oxide. Typically, the metal oxide comprises the oxide of a single metal selected from, but not limited to, transition metals (e.g., iron, cobalt, nickel, vanadium, copper, zinc, zirconium, tungsten, ruthenium, platinum, palladium, molybdenum, osmium, manganese, chromium, titanium, rhodium, ruthenium, iridium), alkaline earth metals (e.g., magnesium, calcium, strontium, and barium), and poor metals/metalloids (e.g., zinc, gallium, aluminum, germanium, tin, and bismuth). Specific examples of metal oxides include, but are not limited to, Al₂O₃, NH₄OSbW, Sb₂O₅, BaO, BaTiO₃, BaZrO₃, Al₆BeO₁₀, BeO, Bi₂O₃, Bi₂O₅, B₂O₃, CdO, CaO, Ce₂O₃, CeO₂, CrO, Cr₂O₃, CrO₂, CrO₃, CoO, Co₂O₃, Cu₂O₅Yb₂, Cu₂O, CuFe₂O₄, CuO, GaO, Ga₂O₃, GeO, GeO₂, Au₂O, Au₂O₃, HfO₂, In₂O, InO, In₂O₃, Ir₂O₃, IrO₂, Fe₃O₄, FeO, Fe₂O₃, PbO, PbO₂, Li₂O, Al₂MgO₄, MgO, Mn₃O₄, MnO, Mn₂O₃, MnO₂, Mn₂O₅, Mn₂O₇, Hg₂O, HgO, MoO₂, MoO₃, Mo₂O₅, NiFe₂O₄, NiO, Ni₂O₃, LiNbO₃, NaNbO₃, Nb₂O₃, Nb₂O₅, Os₂O₃, OsO₃, OsO₄, PdO, PdO₂, (C₆H₅)AsO, Pt₃O₄, PtO, Pt₂O₃, K₂O, Re₂O₇, ReO₄, Rh₂O₃, Rb₂O, RuO₂, RuO₄, Sc₂O₃, Se₃O₄, Ag₂O, Na₂O, SrO, NaTaO₃, Ta₂O₃, Ta₂O₅, SiO₂, SnO, SnO₂, SrTiO₃, TiO, Ti₂O₃, TiO₂, WC1₂O₂, W₂O₃, W^{O}₂, W^{O}₃, W₂O₅, VOCl₂, VO, V₂O₃, VO₂, V₂O₅, Yb₂O₃, YBa₂Cu₃O₇, Y₂O₃, ZnO, ZrO₂, fluorine doped tin oxide, iron doped titanium oxide, WO₃ doped ZnO, Fe doped CeO₂, tin doped Fe₃O₄, and indium tin oxide. In regards to alloys, the alloy may be a mixture of a metal and another element, or a mixture of metals. If there is a mixture of only two types of atoms (not counting impurities) then it is a binary alloy. Examples of binary alloys include, but are not limited to, iron/cobalt, iron/nickel, cobalt/nickel, cobalt/aluminum, nickel/aluminum, iron/aluminum, iron/cerium, iron/molybdenum, iron/copper, iron/iridium, iron/manganese, iron/tin, and iron/niobium. If there is a mixture of three types of atoms (not counting impurities) then it is a ternary alloy. Examples of ternary alloys include, but are not limited to, iron/cobalt/nickel, iron/aluminum/nickel, aluminum/cobalt/nickel, and aluminum/cobalt/iron.

The disclosure also provides for heterogeneous electrocatalysts which comprise a conductive electrocatalytic substrate comprised of one or more conductive, semiconductive and/or superconductive materials that has been coated on one or more surfaces with a thin layer(s) of one or more conductive or semiconductive materials. In a particular embodiment, the heterogeneous electrocatalysts comprise a conductive electrocatalytic substrate and thin layer(s) that are comprised of different materials. In another embodiment, the heterogeneous electrocatalysts comprise a conductive electrocatalytic substrate made of a conductive material and thin layer(s) that are comprised of conductive materials. In yet another embodiment, the heterogeneous electrocatalysts comprise a conductive electrocatalytic substrate that is comprised of a semiconductive material and thin layer(s) that are comprised of semiconductive materials. In a further embodiment, the heterogeneous electrocatalysts comprise a conductive electrocatalytic substrate that is comprised of a semiconductive material and thin layer(s) that are comprised of conductive materials. In another embodiment, a heterogeneous electrocatalyst disclosed herein comprises a thin layer(s) of one or more conductive or semiconductive materials that has a thickness of <50 nm, <25 nm, <10 nm, <5 nm, <1 nm, <9 Å, <8 Å, <7 Å, <6 Å, <5 Å, <4 Å, <3 Å, <2 Å, <1 Å, or <0.5 Å. In yet another embodiment, a heterogeneous electrocatalyst disclosed herein comprises a thin layer(s) of one or more conductive and/or semiconductive materials that have a thickness of 0.1 Å, 0.2 Å, 0.3 Å, 0.4 Å, 0.5 Å, 0.6 Å, 0.7 Å, 0.8 Å, 0.9 Å, 1 Å, 1.1 Å, 1.2 Å, 1.3 Å, 1.4 Å, 1.5 Å, 1.6 Å, 1.7 Å, 1.8 Å, 1.9 Å, 2 Å, 2.1 Å, 2.2 Å, 2.3 Å, 2.4 Å, 2.5 Å, 2.6 Å, 2.7 Å, 2.8 Å, 2.9 Å, 3 Å, 3.1 Å, 3.2 Å, 3.3 Å, 3.4 Å, 3.5 Å, 3.6 Å, 3.7 Å, 3.8 Å, 3.9 Å, 4 Å, 4.1 Å, 4.2 Å, 4.3 Å, 4.4 Å, 4.5 Å, 4.6 Å, 4.7 Å, 4.8 Å, 4.9 Å, 5 Å, 5.1 Å, 5.2 Å, 5.3 Å, 5.4 Å, 5.5 Å, 5.6 Å, 5.7 Å, 5.8 Å, 5.9 Å, 6 Å, 6.1 Å, 6.2 Å, 6.3 Å, 6.4 Å, 6.5 Å, 6.6 Å, 6.7 Å, 6.8 Å, 6.9 Å, 7 Å, 7.1 Å, 7.2 Å, 7.3 Å, 7.4 Å, 7.5 Å, 7.6 Å, 7.7 Å, 7.8 Å, 7.9 Å, 8 Å, 8.1 Å, 8.2 Å, 8.3 Å, 8.4 Å, 8.5 Å, 8.6 Å, 8.7 Å, 8.8 Å, 8.9 Å, 9 Å, 9.1 Å, 9.2 Å, 9.3 Å, 9.4 Å, 9.5 Å, 9.6 Å, 9.7 Å, 9.8 Å, 9.9 Å, 1 nm, 2 nm, 3 nm, 4 nm, 5 nm, 6 nm, 7 nm, 8 nm, 9 nm, 10 nm, 12 nm, 14 nm, 15 nm, 16 nm, 18 nm, 20 nm, 25 nm, 30 nm, 35 nm, 40 nm, 45 nm, 50 nm, or a range including or between any two of the foregoing numbers. In a certain embodiment, a heterogeneous electrocatalyst disclosed herein comprises a thin layer(s) of one or more conductive and/or semiconductive materials that has a thickness resulting from using an ALD process with 1 to 1000 cycles, 1 to 500 cycles, 1 to 100 cycles, 1 to 90 cycles, 1 to 80 cycles, 1 to 70 cycles, 1 to 60 cycles, 1 to 55 cycles, 1 to 50 cycles, 1 to 45 cycles, 1 to 40 cycles, 1 to 35 cycles, 1 to 30 cycles, 1 to 25 cycles, 1 to 24 cycles, 1 to 23 cycles, 1 to 22 cycles, 1 to 21 cycles, 1 to 20 cycles, 1 to 19 cycles, 1 to 18, cycles, 1 to 17 cycles, 1 to 16 cycles, 1 to 15 cycles, 1 to 14 cycles, 1 to 13 cycles, 1 to 12 cycles, 1 to 11 cycles, 1 to 10 cycles, 1 to 9 cycles, 1 to 7 cycles, 1 to 6 cycles or 1 to 5 cycles. In yet another embodiment, a heterogeneous electrocatalyst disclosed herein comprises a thin layer(s) of one or more conductive and/or semiconductive materials that has a thickness resulting from using an ALD process with 1 cycle, 2 cycles, 3 cycles, 4 cycles, 5 cycles, 6 cycles, 7 cycles, 8 cycles, 9 cycles, 10 cycles, 11 cycles, 12 cycles, 13 cycles, 14 cycles, 15 cycles, 16 cycles, 17 cycles, 18 cycles, 19 cycles, 20 cycles, 21 cycles, 22 cycles, 23 cycles, 24 cycles, 25 cycles, 30 cycles, 35 cycles, 40 cycles, 45 cycles, 50 cycles, 55 cycles, 60 cycles, 70 cycles, 80 cycles, 90 cycles, 100 cycles, 500 cycles, 1000 cycles, or any range between any two of the foregoing cycle numbers. In yet another embodiment, a heterogeneous electrocatalyst disclosed herein comprises a conductive electrocatalytic substrate that is ≧100 nm, ≧1 μm, ≧10 μm, ≧100 μm or ≧1 mm in thickness.

In a certain embodiment, the disclosure provides for a heterogeneous electrocatalyst that is suitable for the Oxygen Evolution Reaction which comprises a conductive electrocatalytic substrate comprised of one or more conductive, semiconductive and/or superconductive materials that has been coated on one or more surfaces with a thin layer(s) of one or more conductive or semiconductive materials, and wherein the substrate and thin films are selected from the following materials: NiO₂ and WO₃, NiO₂ and WO₃, NiO₂ and Al₂O₃, NiO₂ and MnO₂, RuO₂ and TiO₂, RuO₂ and WO₃, RuO₂ and Al₂O₃, RuO₂ and MnO₂, CuO₂ and TiO₂, CuO₂ and WO₃, CuO₂ and Al₂O₃, CuO₂ and MnO₂, IrO₂ and TiO₂, IrO₂ and WO₃, IrO₂ and Al₂O₃, IrO₂ and MnO₂, SnO₂/FTO and TiO₂, SnO₂/FTO and WO₃, SnO₂/FTO and Al₂O₃, and SnO₂/FTO and MnO₂.

In an alternate embodiment, the disclosure provides for a heterogeneous electrocatalyst that is suitable for the Nitrogen Reduction Reaction which comprises a conductive electrocatalytic substrate comprised of one or more conductive, semiconductive and/or superconductive materials that has been coated on one or more surfaces with a thin layer(s) of one or more conductive or semiconductive materials, and wherein the substrate and thin films are selected from the following materials: Ni and Ti, Cu and Ti, Nb and Ti, Mo and Ti, Tc and Ti, Ru and Ti, Rh and Ti, Ag and Ti, Sn and Ti, Os and Ti, Ir and Ti, Ni and Mn, Cu and Mn, Nb and Mn, Mo and Mn, Tc and Mn, Ru and Mn, Rh and Mn, Ag and Mn, Sn and Mn, Os and Mn, Ir and Mn, Ni and Zn, Cu and Zn, Nb and Zn, Mo and Zn, Tc and Zn, Ru and Zn, Rh and Zn, Ag and Zn, Sn and Zn, Os and Zn, and Ir and Zn.

In a further alternate embodiment, the disclosure provides for a heterogeneous electrocatalyst that is suitable for the CO₂ Reduction Reaction which comprises a conductive electrocatalytic substrate comprised of one or more conductive, semiconductive and/or superconductive materials that has been coated on one or more surfaces with a thin layer(s) of one or more conductive or semiconductive materials, and wherein the substrate and thin films are selected from the following materials: Ni and Ti, Ni and W, Ni and Al, Ni and Mn, Ru and Ti, Ru and W, Ru and Al, Ru and Mn, Cu and Ti, Cu and W, Cu and Al, Cu and Mn, Ir and Ti, Ir and W, Ir and Al, Ir and Mn, Sn and Ti, Sn and W, Sn and Al, and Sn and Mn.

The disclosure further provides for one or more electrodes which comprises one or more heterogeneous electrocatalysts disclosed herein. In a particular embodiment, an anode comprises one or more heterogeneous electrocatalysts disclosed herein. In an alternate embodiment, a cathode comprises one or more heterogeneous electrocatalysts disclosed herein. In a further alternate embodiment, a cathode and an anode comprises one or more heterogeneous electrocatalysts disclosed herein. In further embodiment, an electrode which comprises one or more heterogeneous electrocatalysts disclosed herein is used in an electrochemical reaction. Examples of electrochemical reactions, include but are not limited to, the chlorine evolution reaction, the oxygen evolution reaction, the hydrogen evolution reaction, the carbon dioxide reduction reaction, the electrochemical water splitting reaction, the nitrogen reduction reaction, and the oxygen reduction reaction.

The following examples are intended to illustrate but not limit the disclosure. While they are typical of those that might be used, other procedures known to those skilled in the art may alternatively be used.

### EXAMPLES

Sample Preparation: [100] boron doped p+, <0.01 Ω-cm, 525+/−25 μm thick silicon wafers were obtained from Addison Engineering. Wafers were cleaned for 1 minute in buffered HF (Transene, used as received), and then immediately put under vacuum of at least 7×10⁻⁶ torr. RuO₂ or IrO₂ were deposited on the wafer using a AJA International Inc. Orion sputter deposition system equipped with Phase II-J software. For sputtering, samples were heated to 400° C. and sputtered with Ir or Ru plasma with a pressure of 20 torr argon and 3 torr oxygen for 22 minutes 25 seconds for Ir and a pressure of 15 torr argon and 5 torr oxygen for 18 minutes for Ru. 0-1000 TiO₂ ALD cycles were deposited on the exposed Si wafer/IrO₂ at 150° C. using an Ultratech Fiji 200 Plasma Atomic Layer Deposition System. Prior to the ALD, one pulse of 0.06 s H₂O was applied onto the sample. Each ALD cycle consisted of a 0.25 s pulse of tetrakis (dimethylamido) titanium (TDMAT, Sigma-Aldrich, 99.999%, used as received), followed by a 0.06 s pulse of H₂O (18 MΩ·cm, Millipore). A 15 s purge under a constant 0.13 L min⁻¹ flow of research-grade Ar (g) was performed between each precursor pulse. The base pressure during the TiO₂ growth was kept at ˜0.1 torr. Growth rate of TiO₂ was ˜0.05 nm/cycle. Bare IrO₂ samples were subjected to only one pulse of 0.06 s H₂O.

Tafel Analysis: Galium-Indium eutectic (Alfa-Aesar, 99.99%) was scribed into the backside of the Si wafer electrode using a tungsten carbide scribe (VWR). A copper wire was then stuck to the Ga—In and secured with one sided copper foil tape (3M) to provide the electrode contact. Samples were then covered in 470 electroplating tape (3M) which had a 2, 3, or 4 mm diameter punched circle in it to expose a constant electrode area. CVs were then performed on a Bio-Logic VSP 300 potentiostat using a 1M KCl Ag/AgCl reference electrode (CH instruments). 5M NaCl at pH 1 was prepared by dissolving 5 mol of reagent grade NaCl (Macron) into 900 mL of water (18 MΩ·cm, Millipore). The pH was adjusted to a pH of 1 using 37% reagent grade HCl (Sigma-Aldrich), and then diluted to 1 L with water (18 MΩ·cm, Millipore). Constant stirring was used during CVs, and a coiled 0.5 mm Pt wire counter electrode was used (Sigma-Aldrich, 99.99%). At least three different samples for each TiO₂ thickness were compared for at least 10 cycles from 0.9 to 1.4 V vs Ag/AgCl. Peak current was similar for the 10 cycles of any given sample, and surface area did not significantly change before and after cyclic voltammetry and, surface area as measured by integrating the non-faradaic current on the CVs was similar between samples. CV current data was converted to mA/cm² units and then logged to perform Tafel analysis. Overpotentials and exchange current densities were averaged from at least three different samples. Overpotential calculations were conducted using the Nernst equation and activities of Cl⁻ and Cl₂. Cl₂ is a gas so fugacity was used while Cl⁻ activities were estimated from ionic strength. Thermodynamic potential was calculated to be 1094 mV vs an Ag/AgCl reference electrode.

Electrochemical Impedance Spectroscopy: 5M NaNO₃ at pH 1 was prepared by dissolving NaNO₃ (J.T. Baker, 99.6%) in 900 mL of water (18 MΩ·cm, Millipore), adjusting the pH to 1 using HNO₃ (Sigma Aldrich, 60%) and diluting with water (18 MΩ·m, Millipore) to 1 L. Electrodes were prepared as previously described and placed in sealed custom glass reaction containers with a 1M KCl Ag/AgCl reference electrode (CH instruments), 2×2 cm stainless steel counter electrode and enough NaNO₃ solution to cover the exposed 2 mm diameter anode. The reaction container was then purged with N₂ for >30 minutes. Impedance measurements were carried out using Bio-Logic potentiostat/galvanostat model VSP-300 with EIS capability. All studies were performed at 298±2 K. Impedance spectra were recorded in the frequency range of 1 MHz to 10 mHz, and the modulation amplitude of 5 mV. Potential range was 1.1 V to 0V versus a Ag/AgCl reference electrode at a step size of 25 mV.

EIS data were fitted, using ZView software, to a Rs-(Rp-CPE) circuit, where Rs is solution resistance in high frequencies, CPE is a Constance Phase Element that represents double layer capacitance in mid-range frequencies, and Rp is charge transfer resistance at low frequencies. Spectroscopy was then redone on new samples in the range of the E_{PZE} to confirm accuracy.

Initial Electrocatalytic Studies with TiO₂ Coated IrO₂ in the Chlorine Evolution Reaction: The most active electrocatalyst (stability not withstanding) for the chlorine evolution reaction is RuO₂ and the second most active is IrO₂. While IrO₂ operates at a higher overpotential for a given surface area (˜50 mV or higher) than RuO₂, RuO₂ use is limited by its instability. Measurements of the metal-oxygen bond strength and electron density of the surface metal and oxygen by x-ray photoelectron spectroscopy in RuO₂ and IrO₂ indicate that the surface oxygen on RuO₂ is more electron rich and the metal is more electron poor than the surface oxygen and metal on IrO₂. It is likely that this disparity accounts for the difference in the activity between the two catalysts.

The important surface electronic state of the two catalysts can be experimentally characterized by the relative potentials of zero charge (E_{PZC}), heat of formation, electron affinity measurements and others. Here we used E_{PZC} to approximate electronic states. Absolute E_{PZE} can vary considerably with electrolyte conditions (reported values for TiO₂ are between −790 to 570 mV vs Ag/AgCl), however trends within a given electrolyte are consistent across electrolytes and are also negatively linearly correlated with the isoelectric point (IEP) (which also varies considerably with electrolyte). The reported IEP trend in a 1M NaNO₃ electrolyte is an IEP of 5.3-5.5 for IrO₂, which is less than the RuO₂ that has an IEP of 4. Based on the established trend, these values predict that RuO₂ should have a ˜20 mV higher E_{PZC} than IrO₂. This trend agrees well with the measured values of E_{PZC} in 5M NaNO₃, pH 1, where IrO₂ has an E_{PZC} of 100 mV vs Ag/AgCl; and RuO₂ has an E_{PZC} of 125 mV vs Ag/AgCl.

It was hypothesized that by overlaying IrO₂ with a very thin coat of a metal-oxide that has a much more oxidative E_{PZC} than IrO₂, it would be possible to tune the electronics of the underlying IrO₂ such that the surface had electronics similar to RuO₂. For this purpose, TiO₂ was used, which has a measured E_{PZC} of 475 mV vs Ag/AgCl in 5M NaNO₃, pH 1 (within the range of reported values). Aside from having the desirable E_{pzc}, TiO₂ was also chosen because it conveys high stability to IrO₂ catalysts, and can be conveniently deposited by ALD.

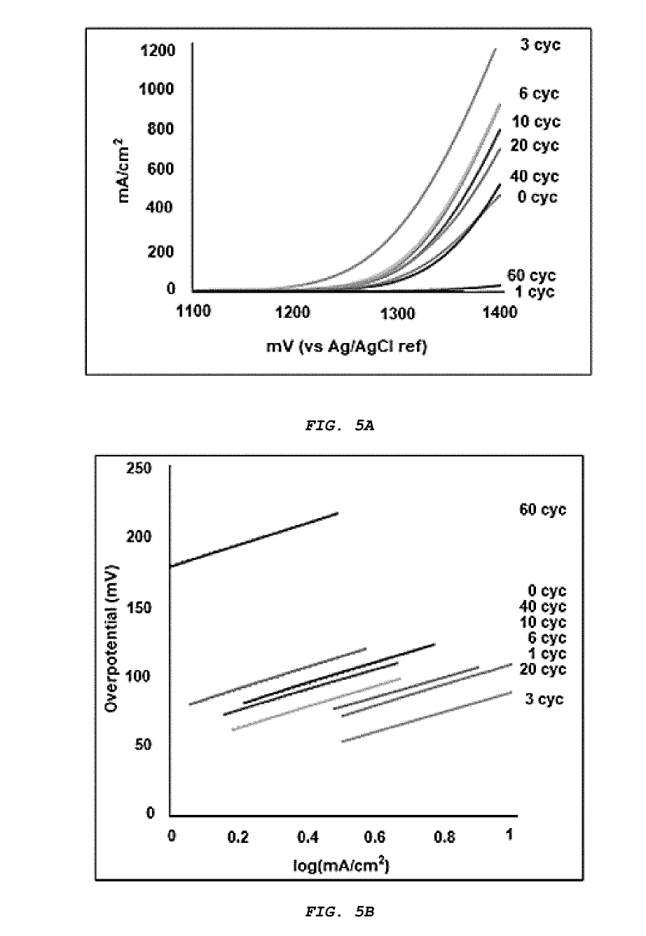

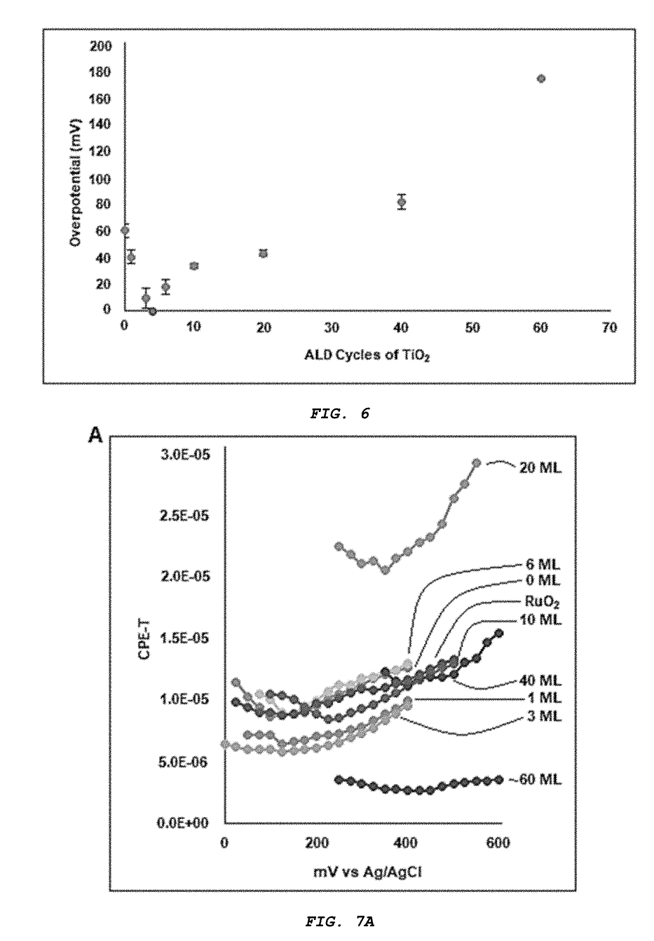

To measure catalytic change in IrO₂ by ALD, IrO₂ was deposited on atomically flat p+ [100] silicon wafers by reactive sputtering for a nearly flat surface. ALD was then used to chemically bond 0-1000 ALD cycles of TiO₂ to the IrO₂ surface (thick films of TiO₂ are nearly inert for the chlorine evolution reaction at reasonable overpotentials). Polarization curves for TiO₂ coated IrO₂ and bare IrO₂ were measured and Tafel analysis was conducted (see FIGS. 5A and B). All polarization curves were performed in 5 M NaCl, pH 2 to ensure no significant oxygen evolution in the potential range tested.

It was found that the reaction operated under a constant mechanism with Tafel slopes varying between 72 and 78 mV/decade. The traditionally measured catalytic parameter is activation energy. However, overpotential was measured herein. The Y intercept marks the onset potential for chlorine evolution. These potentials were graphed in FIG. 6 with RuO₂, the optimal catalyst, which is shown for comparison.

These data indicate that increasing the number of ALD cycles of TiO2 can alter the onset potential of the catalyst. This effect follows a Sabatier principle type volcano plot (see FIG. 2), where the TiO₂ ALD cycles appear to be most beneficial at 3 ALD cycles of TiO₂, and less beneficial when less than three ALD cycles was used. Interestingly, the onset potential for the CER for IrO₂ coated with 3 ALD cycles of TiO2 is not significantly different from the fully optimized onset potential of RuO2 (˜1 mV in concentrated brine).

To investigate the role of surface electronics, impedance spectroscopy was preformed to determine the EPZC for these electrodes. In these experiments, the capacitance of an electrode was measured in an inert ionic solution. The capacitance will be lowest at the EPZC as an uncharged surface attracts the smallest double layer. These experiments were conducted at the same ionic strength and pH as the polarization curve experiments except that NaCl was replaced with the oxidatively inert salt, NaNO3. The EPZC is a measure of the surface electronics, the more negative charge character a surface has, the higher the EPZC, and the less negative charge character a surface has the lower the EPZC.

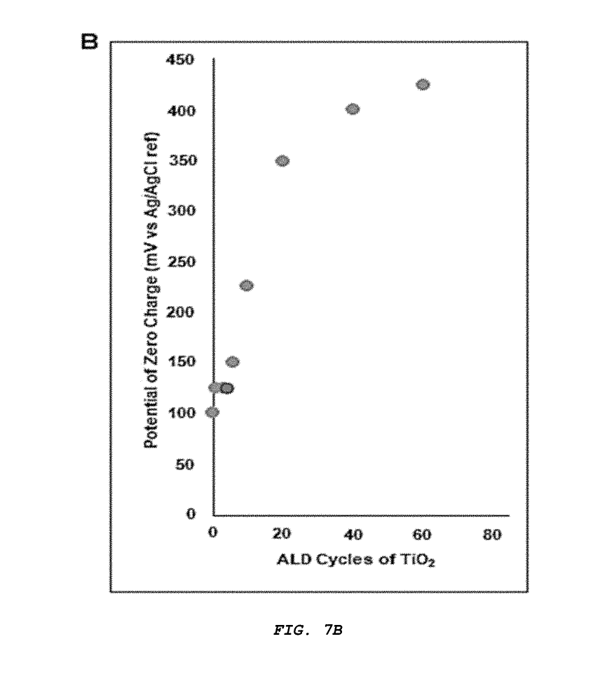

FIGS. 7A and B indicate that the E_{PZC} follows the established trend and was in good agreement with predicted values. It was found that the surface E_{PZC} varies incrementally with added TiO₂ up until the curve flattens somewhat for thick (>20 ALD cycles, -1nm), highly resistive films of TiO₂ (1000 ALD cycles of TiO₂ yield an E_{PZC} of 475 mV vs Ag/AgCl) and chracterisitc inert CER activity due to poor conductivity. These data show that the surface electronics of the IrO₂/TiO₂ system can be altered by applying very thin films of the highly oxidative E_{PZC} TiO₂ on top of the less oxidative E_{PZC} IrO₂.

Additional Electrocatalytic Studies with TiO₂ Coated IrO₂ in the Chlorine Evolution Reaction: Computational studies show that the Cl⁻ is most likely to coordinate onto the oxygen on the M-O surface, this means that the electronics of that oxygen are likely very important for the CER. XPS measured electron configurations and electronegativities imply that IrO₂ has a less electron dense terminal O atom than RuO₂ and both IrO₂ and RuO₂ have a much less electron rich 0 atom than TiO₂. Therefore, adding one ALD cycle of TiO₂ could significantly alter the electronic state of the surface Oxygen and could account for the observed altered electronics and the fully optimized (˜0 mV) overpoentenial for CER in concentrated brine.

To this end, samples of IrO₂ were prepared with different numbers of atomic layer deposition (ALD) cycles of TiO₂ deposited on top the IrO₂ substrate in order to tune the charge density of the catalyst's surface. The layer thickness using ALD can be controlled down to a single monolayer. ALD is a mature technology that has been used extensively in the microelectronics industry to vary the surface charge density of semiconductors by depositing thin layers of gate oxides. Here, IrO₂ was coated with between 1 and 60 ALD cycles of TiO₂. The catalytic performance of these samples for the CER was measured under conditions similar to industrial CER (i.e., 5 M Cl⁻, pH 1) in order to eliminate competition with OER. Metal oxide charge densities were evaluated by measuring the correlated potential of zero charge (E_{PZC}), the potential for a given electrode in a given solution where the net surface charge is zero (i.e., a metal oxide with a more electron rich oxygen and more electron poor metal has a higher E_{PZC}).

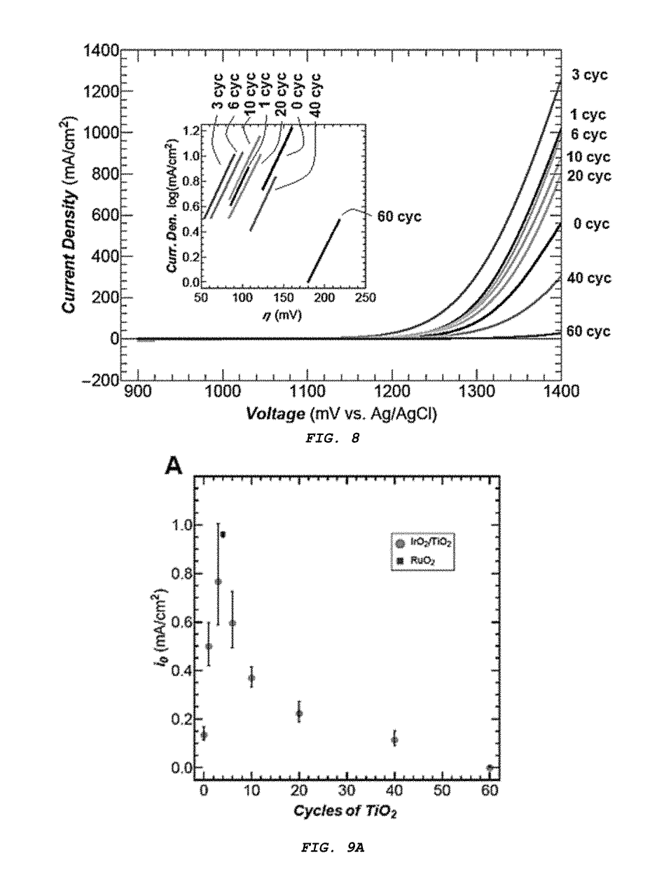

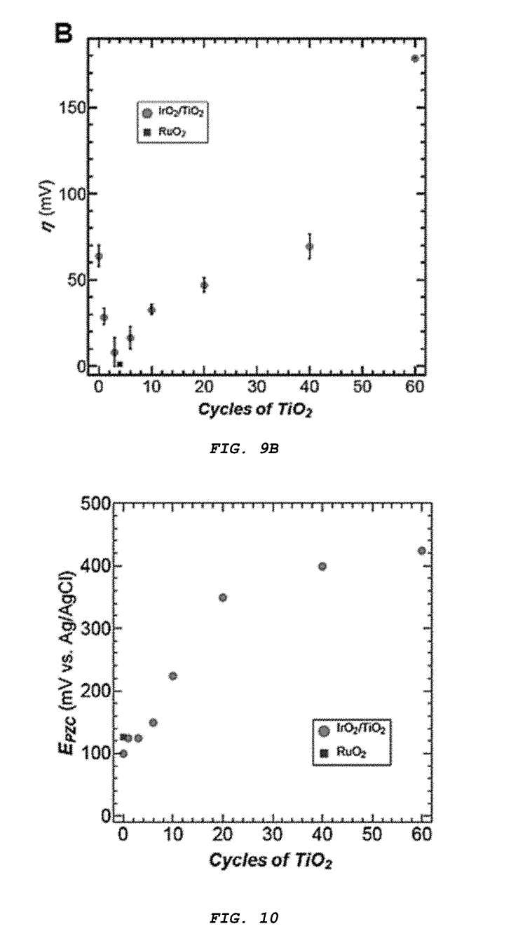

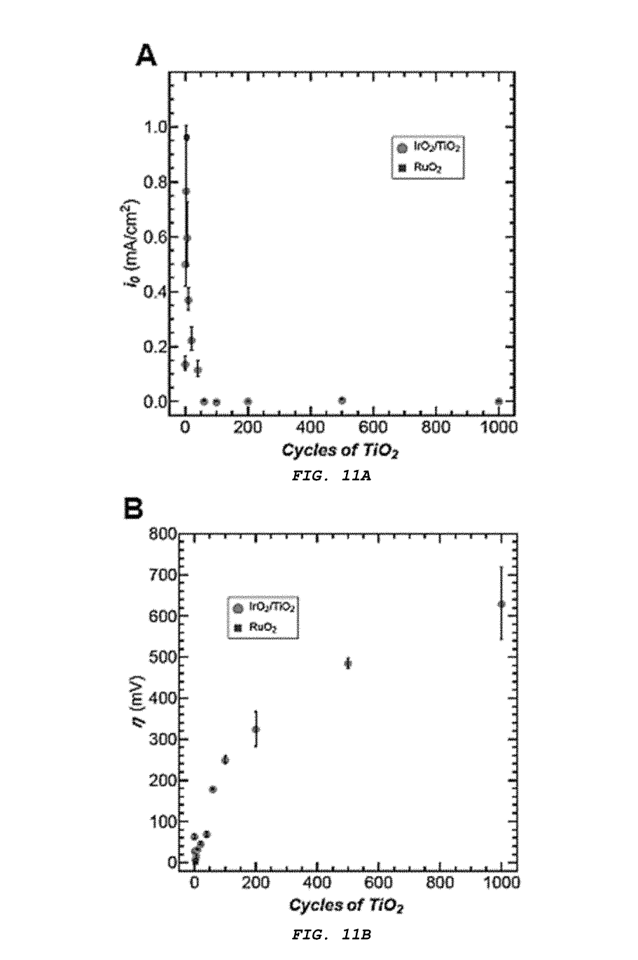

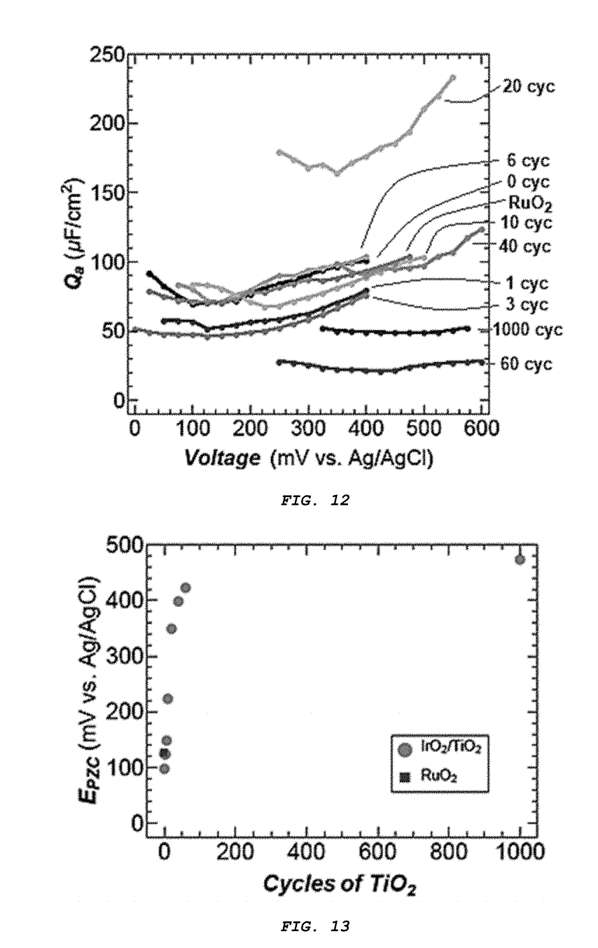

The catalytic performance of IrO₂ electrocatalysts with varying ALD cycles of TiO₂ is shown in FIG. 8. The additional deposition of TiO₂ on the surface of IrO₂ did not change the CER reaction mechanism as evidenced by the Tafel slopes (72 and 76 mV per decade) in the inset in FIG. 8, which are consistent with the range of values reported in literature for CER. The fundamental measures of an electrocatalyst's activity are the exchange current density (i₀), a measure of the one-way rate of a reaction at equilibrium which is determined by fitting the current-voltage data to the Tafel equation and the overpotential (η), which is a measure of the electrochemical activation energy. While the CER mechanism for all thicknesses of TiO₂ was unchanged, deposition of TiO₂ significantly altered the exchange current density and overpotential, resulting in volcano-shaped plots with optimal performance occurring at 3 ALD cycles, as seen in FIGS. 9A and 9B, respectively. These volcano relations are indicative of the Sabatier principle, which states that the ideal catalytic surface is one that provides “just right” biding of reaction intermediates. Deposition of 3 cycles of TiO₂ resulted in an over fivefold increase in the exchange current density, from 0.14 to 0.77 mA/cm², and a decrease in overpotential by 60 mV, compared to the bare IrO₂ sample. This performance is commensurate with the performance of the best known CER catalyst, RuO₂ (the red square in FIGS. 9A and 9B). Deposition of TiO₂ at thicknesses greater than 60 ALD cycles increased the CER overpotential dramatically, as expected for highly resistive bulk TiO₂ (see FIGS. 11A and B).

Cl⁻ may coordinate either to vacancies on the surface metal or surface bound oxygens, therefore the electron density of the surface oxygen and metal are important parameters governing the activity of CER catalysts. The correlated potential at zero charge is a means of quantifying the surface oxygen and metal charge densities for metal oxides, where higher EPZC values indicate higher electron densities on surface oxygen atoms and electron-poor metal atoms. Previously measured electron configurations, electronegativities, and EPZC values imply that the electron density of the oxygen in the metal oxide bond follows the pattern IrO₂<RuO₂<<TiO₂. However, the Epzc of IrO₂ anodes overcoated with TiO2 increased approximately linearly with increasing TiO₂ thickness, up to 20 ALD cycles, after which increasing the TiO₂ layer thickness resulted in Epzc values that approached those of bulk TiO₂ (see FIG. 10 and FIG. 13). This suggests that deposition of a thin layer of TiO₂ on IrO₂ does not result in the bulk TiO₂ surface species charge densities but rather charge densities that were intermediate to those of IrO₂ and TiO₂. At the optimal TiO₂ thickness for CER catalysis (3 ALD cycles) the Epzc of the IrO₂/TiO₂ sample was virtually indistinguishable from that of RuO₂, indicating that the surface oxygen and surface metal charge densities can be tuned to produce an ideal binding environment for catalysis.

In order to further investigate the effect of thin layers of TiO₂ on the catalytic performance of IrO₂, density functional theory (DFT) was used to calculate how the free energy of chlorine adsorption to the IrO₂ surface is altered by adding layers of TiO₂. The CER proceeds through the Volmer-Heyvrosky mechanism,

*+Cl⁻═Cl*+e⁻ (1)

Cl*+Cl⁻═C1₂+e⁻ (2)

where * stands for an active adsorption site. On the rutile IrO₂ (110) surface, the active site for chlorine adsorption is proposed to be a surface oxygen atom which has adsorbed on a coordinately unsaturated (cus) Ir site. However, chlorine adsorption is activated directly on the cus Ti site on the TiO₂ covered IrO₂ surfaces, because the adsorption energies of oxygen on cus Ti site are prohibitively large. According to the Volmer-Heyvrosky mechanism, the sign of free energy of binding Cl⁻ to the active site (AG(Cl*)) dictates whether the Volmer step (1) or the Heyvrosky step (2) is rate-determining, while the magnitude of AG(Cl*) determines the overpotential for CER. Thus, AG(Cl*) for the bare IrO₂ (110) surface and with one, two, and three layers (1L, 2L, 3L) of TiO₂, was calculated using DFT. As the number of simulated TiO₂ layers increases from 1 to 3, the |ΔG(Cl*)| decreases from 0.28 eV to 0.07 eV, indicating a reduction in overpotential and increase in catalytic activity with the incorporation of TiO₂. The sign of AG(Cl*) changes from 2L to 3L, such that further increasing the number of TiO₂ layers beyond 3 leads to an increase in |ΔG(Cl*)|, and therefore an increase in the overpotential for CER. These computational results support the experimental findings that adding a very thin layer of TiO₂ to IrO₂ improves the catalytic performance for the CER.

These data indicate that adding various layers of a metal oxide with a more electron poor metal and more electron rich oxygen on top of a metal oxide with a less electron poor metal and less electron rich oxygen can tune the surface charge density and the catalytic parameters. Furthermore, these data show that when the charge density is matched to that of a better catalyst, the catalytic parameters also match as predicted by the Sabatier principal. Therefore, the methods of the disclosure represent a new tool for improving the performance of heterogeneous electrocatalysts by tuning an active surface species' charge density by overcoating with an appropriate material or mix of materials. Furthermore, this technique may provide a pathway to enhance the catalytic activity of earth abundant electrocatalysts for critical reactions that was not previously available due to a dearth of tools to tune the activity of heterogeneous electrocatalysts.

The foregoing additionally demonstrates that the surface electronics of any substrate could be tuned by combining two materials that have different electronic properties in thin layers. This tuning could allow the surface electronics to match the requisites of any chemical reaction of interest. Combinations of 2 or more metal—nonmetal materials may be deposited to achieve a perfect electronic state of the surface. It is further postulated that tuning could be performed with earth abundant or non-precious metal-nonmetal electrodes in order to fit a chemically active regime.

Additional Electrocatalytic Studies with four different materials coated with TiOx in the Chlorine Evolution Reaction and Oxygen Evolution Reaction: Additional catalysts were created (>50) for the study of two industrially important electrochemical reactions (the chlorine evolution reaction (CER) and the oxygen evolution reaction (OER)). In the studies, 4 different materials (fluorine doped tin oxide (FTC)), iridium oxide (IrOₓ), ruthenium oxide (RuOₓ), and titania (TiOₓ)) were utilized. TiOₓ was deposited as atomically thin layers ((from a single atomic layer (<0.5 angstroms) to 1000 atomic layers (approximately 50 nm)) on top of a FTO, IrOₓ, and RuOₓ substrate, where a new catalyst was created for each thickness of TiOₓ.

In was found that the electrocatalysts made by the methods disclosed herein had improved catalytic activity for the OER in comparison to the best industry catalysts. For example, the current best electrocatalyst for the OER in 1 M H₂SO₄ is RuO₂ which operates at a specific activity (normalized to electrochemically active surface area) of 0.42 mA/cm² at 350 mV overpotential. By using the methods presented herein, a new heterogeneous electrocatalyst was made by layering 10 cycles of TiO₂ onto IrOₓ was found to operate at a specific activity of 3.5 mA/cm² at 350 mV overpotential. Further, a new heterogeneous electrocatalyst made by layering 10 cycles of TiOₓ onto RuO₂ using the methods of the disclosure, yielded a heterogeneous electrocatalyst that operated at of 2.8 mA/cm² at 350 mV overpotential for the OER.

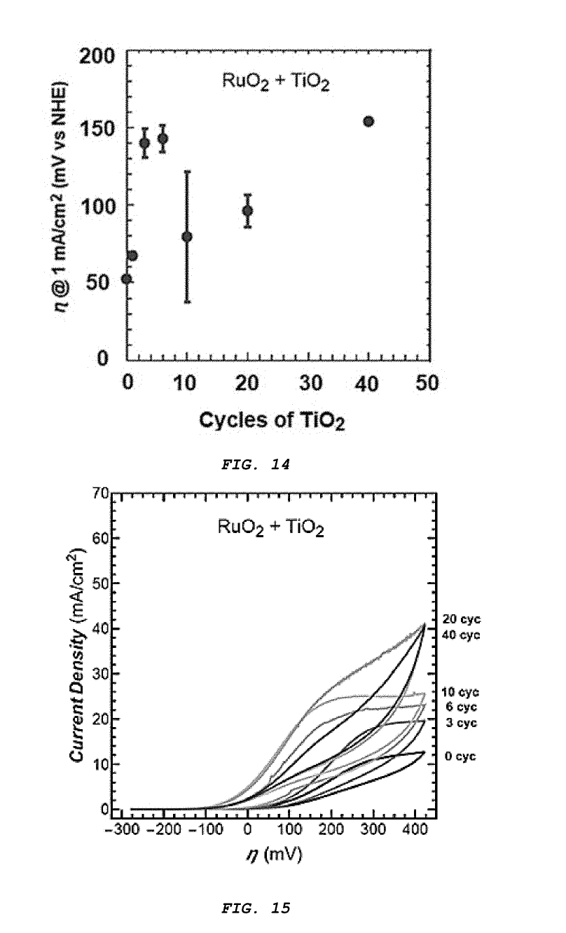

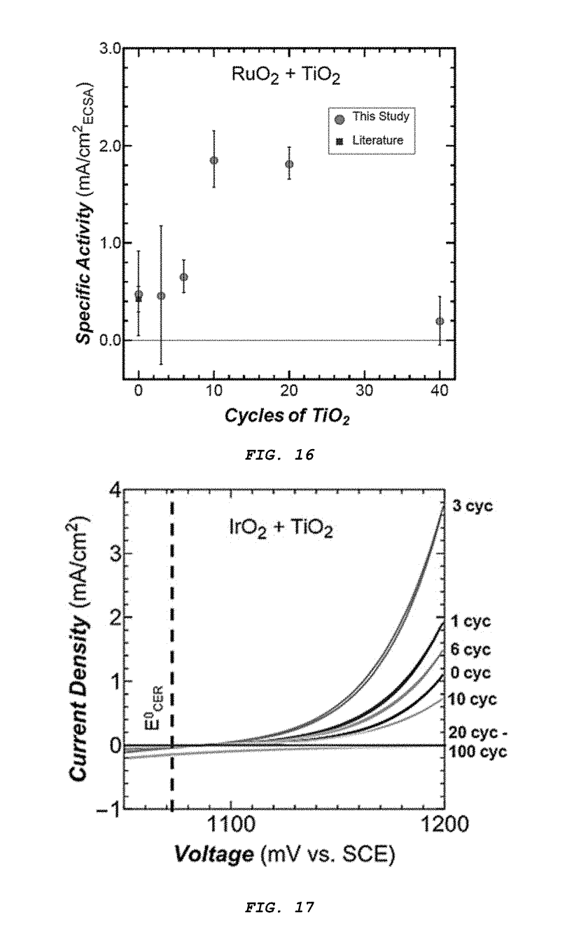

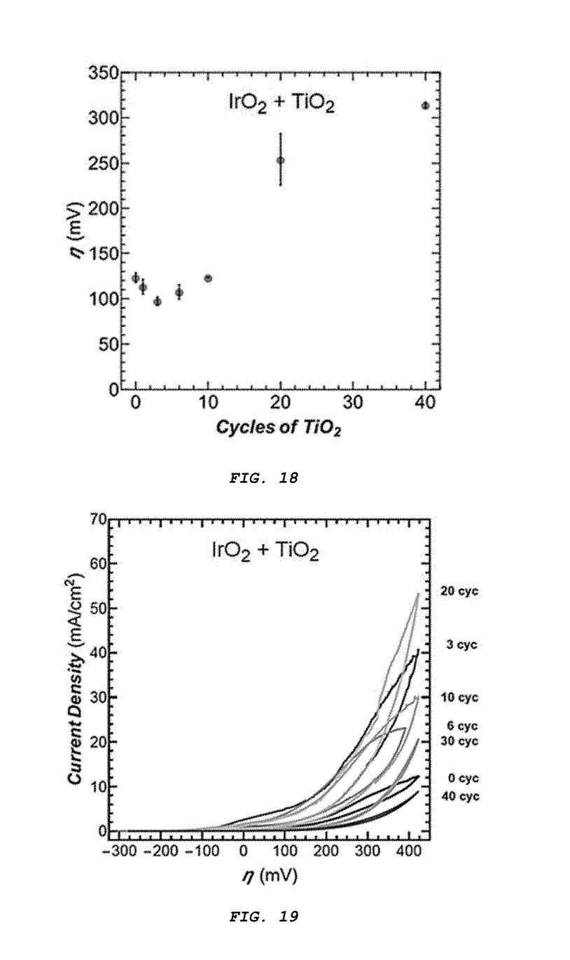

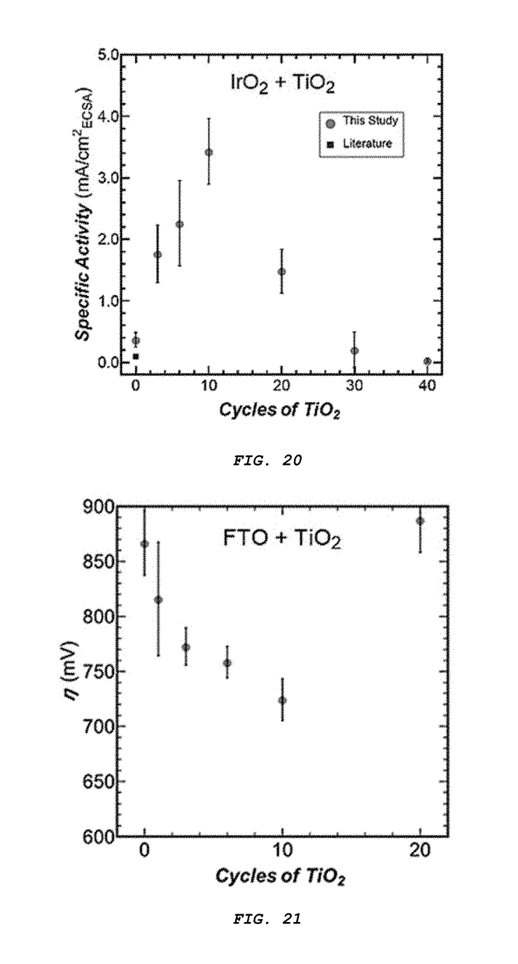

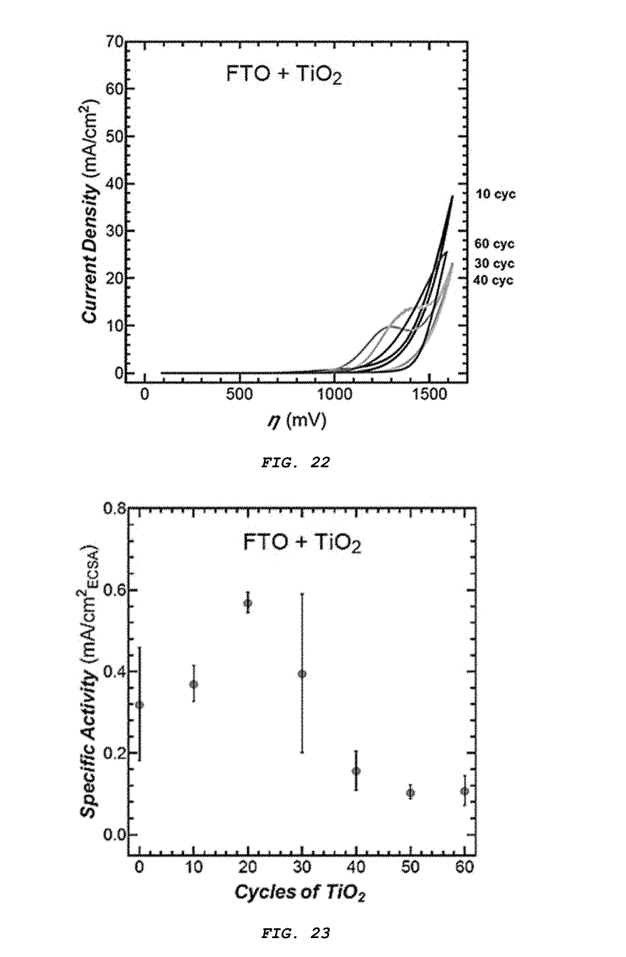

The overpotentials of RuO₂ coated with increasing ALD cycles of TiO₂ for CER are presented in FIG. 14; while the polarization curves and specific activities for RuO₂ coated with increasing ALD cycles of TiO₂ for OER are presented in FIGS. 15 and 16, respectively. The polarization curves and overpotential curves for IrO₂ coated with increasing ALD cycles of TiO₂ for CER are presented in FIGS. 17 and 18, respectively; while the polarization curves and specific activities for IrO₂ coated with increasing ALD cycles of TiO₂ for CER are presented in FIGS. 19 and 20, respectively. The overpotentials of FTO coated with increasing ALD cycles of TiO₂ for CER are presented in FIG. 21; while the polarization curves and specific activities for FTO coated with increasing ALD cycles of TiO₂ for OER are presented in FIGS. 22 and 23, respectively.

It will be understood that various modifications may be made without departing from the spirit and scope of this disclosure. Accordingly, other embodiments are within the scope of the following claims.

What is claimed is:

1. A method to manufacture a heterogeneous electrocatalyst that has improved electrocatalytic activity for an electrochemical reaction, comprising:
layering or depositing one or more thin films of one or more conductive and/or semiconductive catalytic materials onto a surface of a conductive electrocatalytic substrate by using 1 to 100 cycles of an atomic layer deposition process,
wherein the composition of the one of more thin films is different from the composition of the conductive electrocatalytic substrate,
wherein the number of cycles of the atomic layer deposition process is used to tune the electrocatalytic activity of the heterogeneous electrocatalysts for the electrochemical reaction,
and wherein the electrocatalytic activity of the heterogeneous electrocatalyst for the electrochemical reaction is improved in comparison to the electrocatalytic activity of the conductive electrocatalytic substrate.

2. The method of claim 1, wherein the one or more thin films are comprised of metals, alloys, metal oxides, metal nitrides, metal sulfides, metal fluorides, or a combination thereof.

3. The method of claim 2, wherein the one of more thin films comprise one or more metal oxides selected from Al₂O₃, NH₄OSbW, Sb₂O₅, BaO, BaTiO₃, BaZrO₃, Al₆BeO₁₀, BeO, Bi₂O₃, Bi₂O₅, B₂O₃, CdO, CaO, Ce₂O₃, CeO₂, CrO, Cr₂O₃, CrO₂, CrO₃, CoO, Co₂O₃, Cu₂O₅Yb₂, Cu₂O, CuFe₂O₄, CuO, GaO, Ga₂O₃, GeO, GeO₂, Au₂O, Au₂O₃, HfO₂, In₂O, InO, In₂O₃, Ir₂O₃, I rO₂, Fe₃O₄, FeO, Fe₂O₃, PbO, PbO₂, Li₂O, Al₂MgO₄, MgO, Mn₃O₄, MnO, Mn₂O₃, MnO₂, Mn₂O₅, Mn₂O₇, Hg₂O, HgO, MoO₂, MoO₃, Mo₂O₅, NiFe₂O₄, NiO, Ni₂O₃, LiNbO₃, NaNbO₃, Nb₂O₃, Nb₂O₅, Os₂O₃, OsO₃, OsO₄, PdO, PdO₂, (C₆H₅)AsO, Pt₃O₄, PtO, Pt₂O₃, K₂O, Re₂O₇, ReO₄, Rh₂O₃, Rb₂O, RuO₂, RuO₄, SC₂O₃, Se₃O₄, Ag₂O, Na₂O, SrO, NaTaO₃, Ta₂O₃, Ta₂O₅, SiO₂, SnO, SnO₂, SrTiO₃, TiO, Ti₂O₃, TiO₂, WCl₂O₂, W₂O₃, WO₂, WO₃, W₂O₅, VOCl₂, VO, V₂O₃, VO₂, V₂O₅, Yb₂O₃, YBa₂Cu₃O₇, Y₂O₃, ZnO, ZrO₂, fluorine doped tin oxide, iron doped titanium oxide, WO₃ doped ZnO, Fe doped CeO₂, tin doped Fe₃O₄, and indium tin oxide.

4. The method of claim 3, wherein the one or more thin films comprise TiO₂.

5. The method of claim 1, wherein 1 to 25 cycles of an atomic layer deposition process are used to deposit or layer one or more thin films onto a surface of the conductive electrocatalytic substrate.

6. The method of claim 1, wherein 1 to 15 cycles of an atomic layer deposition process are used to deposit or layer a thin film of TiO₂ onto a surface of the conductive electrocatalytic substrate.

7. The method of claim 1, wherein the one or more thin films are made from one or more precursors used in the atomic layer deposition process selected from aluminum tris(2,2,6,6-tetramethyl-3,5-heptanedionate), triisobutylaluminum, trimethylaluminum, tris(dimethylamido)aluminum(III), triphenylantimony(III), tris(dimethylamido)antimony(III), triphenylarsine, Triphenylarsine oxide, barium bis(2,2,6,6-tetramethyl-3,5-heptanedionate) hydrate, barium nitrate, Ba(C₉H₂₃N₃)₂ [CₓH_{y}C(O)CHC(O)CₓH_{y}]₂ (x=3-4, y=2x+1), [Ba(C₅(CH₃)₅) ₂].2(C₄H₈O) , [Ba(C₅(C₃H₇)₃H₂)₂].2(C₄H₈O) , bis (acetato-O) triphenylbismuth (V) , triphenylbismuth, tris(2-methoxyphenyl)bismuthine, triisopropyl borate, triphenylborane, tris(pentafluorophenyl)borane, cadmium acetylacetonate, calcium bis(6,6,7,7,8,8,8,-heptafluoro-2,2-dimethyl-3,5-octanedionate), calcium bis(2,2,6,6-tetramethyl-3,5-heptanedionate), bis(cyclopentadienyl)chromium(II), bis(pentamethylcyclopentadienyl)chromium(II), chromium(III) tris(2,2,6,6-tetramethyl-3,5-heptanedionate), bis(cyclopentadienyl)cobalt(II), bis(pentamethylcyclopentadienyl)cobalt(II), copper bis(6,6,7,7,8,8,8-heptafluoro-2,2-dimethyl-3,5-octanedionate), copper bis(2,2,6,6-tetramethyl-3,5-heptanedionate), tris(dimethylamido)gallium(III), germanium(IV) fluoride, hexaethyldigermanium(IV), tetramethylgermanium, tributylgermanium hydride, triethylgermanium hydride, triphenylgermanium hydride, bis(tert-butylcyclopentadienyl)dimethylhafnium(IV), bis(trimethylsilyl)amidohafnium(IV) chloride, dimethylbis(cyclopentadienyl)hafnium(IV), tetrakis(diethylamido)hafnium(IV), tetrakis(dimethylamido)hafnium(IV), tetrakis(ethylmethylamido)hafnium(IV), [1,1′-bis(diphenylphosphino)ferrocene]tetracarbonylmolybdenum(0), bis(pentamethylcyclopentadienyl)iron(II), 1,1′-diethylferrocene, iron(0) pentacarbonyl, iron(III) tris(2,2,6,6-tetramethyl-3,5-heptanedionate), bis(cyclopentadienyl)magnesium(II), bis(pentamethylcyclopentadienyl)magnesium, Mg(C₆H₁₆N₂) [CₓH_{y}C(O)CHC(O)CₓH_{y}]₂ (x=3-4, y=2x+1), bis(pentamethylcyclopentadienyl)manganese(II), bis(tetramethylcyclopentadienyl)manganese(II), bromopentacarbonylmanganese(I), cyclopentadienylmanganese(I) tricarbonyl, ethylcyclopentadienylmanganese(I) tricarbonyl, manganese(0) carbonyl, (bicyclo[2.2.1]hepta-2,5-diene) tetracarbonylmolybdenum(0), bis(cyclopentadienyl)molybdenum(IV) dichloride, cyclopentadienylmolybdenum(II) tricarbonyl dimer, molybdenumhexacarbonyl, (propylcyclopentadienyl)molybdenum(I) tricarbonyl dimer, allyl(cyclopentadienyl)nickel(II), bis(cyclopentadienyl)nickel(II), bis(ethylcyclopentadienyl)nickel(II), nickel(II) bis(2,2,6,6-tetramethyl-3,5-heptanedionate), bis(cyclopentadienyl)niobium(IV) dichloride, trimethyl(methylcyclopentadienyl)platinum(IV), dirhenium decacarbonyl, (acetylacetonato) (1,5-cyclooctadiene)rhodium(I), (acetylacetonato) (1,5-cyclooctadiene)rhodium(I), bis(cyclopentadienyl)ruthenium(II), bis(ethylcyclopentadienyl)ruthenium(II), bis(pentamethylcyclopentadienyl)ruthenium(II), triruthenium dodecacarbonyl, Sr(C₉H₂₃N₃)₂[CₓH_{y}C(O)CHC(O)CₓH_{y}]₂ (x=3-4, y=2x+1), pentakis(dimethylamino)tantalum(V), tantalum(V) ethoxide, tris(diethylamido) (tert-butylimido)tantalum(V), tris(ethylmethylamido) (tert-butylimido)tantalum(V), Ta(C₂H₅O)₄ [CₓH_{y}C(O)CHC(O)CₓHy]₂ (x=3-4, y=2x+1), bis[bis(trimethylsilyl)amino]tin(II), dibutyldiphenyltin, hexaphenylditin(IV), tetraallyltin, tetrakis(diethylamido)tin(IV), tetramethyltin, tetravinyltin, tin(II) acetylacetonate, trimethyl(phenylethynyl)tin, trimethyl(phenyl)tin, tetrakis (dimethylamido)titanium(IV) (TDMAT), tetrakis(ethylmethylamido)titanium(IV), titanium(IV) diisopropoxidebis(2,2,6,6-tetramethyl-3,5-heptanedionate), titanium tetrachloride, titanium(IV) isopropoxide, Ti(OC₃H₇)₂ [CₓH_{y}C(O)CHC(O)CₓH_{y}]₂ (x=3-4, y=2x+1), bis(butylcyclopentadienyl)tungsten(IV) diiodide, bis(tert-butylimino)bis(tert-butylamino)tungsten, bis(tert-butylimino)bis(dimethylamino)tungsten(VI), bis(cyclopentadienyl)tungsten(IV) dichloride, bis(cyclopentadienyl)tungsten(IV) dihydride, bis(isopropylcyclopentadienyl)tungsten(IV) dihydride, cyclopentadienyltungsten(II) tricarbonyl hydride, tetracarbonyl(1,5-cyclooctadiene)tungsten(0), triamminetungsten(IV) tricarbonyl, tungsten hexacarbonyl, bis(cyclopentadienyl)vanadium(II), bis(cyclopentadienyl)vanadium(II), vanadium(V) oxytriisopropoxide, bis(pentafluorophenyl)zinc, bis(2,2,6,6-tetramethyl-3,5-heptanedionato)zinc(II), diethylzinc, and diphenylzinc.

8. The method of claim 7, wherein the one or more thin films are made from a precursor of tetrakis (dimethylamido)titanium(IV) used in the atomic layer deposition process.

9. The method of claim 1, wherein the conductive electrocatalytic substrate is at least 100 nm in thickness.

10. The method of claim 1, wherein the conductive electrocatalytic substrate is comprised of a conductive material, semiconductive material and/or superconductive material.

11. The method of claim 10, wherein the conductive electrocatalytic substrate is comprised of a metal oxide selected from Al₂O₃, NH₄OSbW, Sb₂O₅, BaO, BaTiO₃, BaZrO₃, Al₆BeO₁₀, BeO, Bi₂O₃, Bi₂O₅, B₂O₃, CdO, CaO, Ce₂O₃, Ce O₂, CrO, Cr₂O₃, CrO₂, CrO₃, CoO, Co₂O₃, Cu₂O₅Yb₂, Cu₂O, CuFe₂O₄, CuO, GaO, Ga₂O₃, GeO, GeO₂, Au₂O, Au₂O₃, HfO₂, In₂O, InO, In₂O₃, Ir₂O₃, IrO₂, Fe₃O₄, FeO, Fe₂O₃, PbO, PbO₂, Li₂O, Al₂MgO₄, MgO, Mn₃O₄, MnO, Mn₂O₃, MnO₂, Mn₂O₅, Mn₂O₇, Hg₂O, HgO, MoO₂, MoO₃, Mo₂O₅, NiFe₂O₄, NiO, Ni₂O₃, LiNbO₃, NaNbO₃, Nb₂O₃, Nb₂O₅, Os₂O₃, OsO₃, OsO₄, PdO, PdO₂, (C₆H₅)AsO, Pt₃O₄, PtO, Pt₂O₃, K₂O, Re₂O₇, Re O₄, Rh₂O₃, Rb₂O, RuO₂, RuO₄, Sc₂O₃, Se₃O₄, Ag₂O, Na₂O, SrO, NaTaO₃, Ta₂O₃, Ta₂O₅, SiO₂, SnO, SnO₂, SrTiO₃, TiO, Ti₂O₃, TiO₂, WCl₂O₂, W₂O₃, WO₂, WO₃, W₂O₅, VOCl₂, VO, V₂O₃, VO₂, V₂O₅, Yb₂O₃, YBa₂Cu₃O₇, Y₂O₃, ZnO, ZrO₂, fluorine doped tin oxide, iron doped titanium oxide, WO₃ doped ZnO, Fe doped CeO₂, tin doped Fe₃O₄, and indium tin oxide.

12. The method of claim 11, wherein the conductive electrocatalytic substrate is comprised of IrO₂ or RuO₂.

13. The method of claim 1, wherein the electrochemical reaction is selected from the group consisting of the chlorine evolution reaction, the oxygen evolution reaction, the hydrogen evolution reaction, the carbon dioxide reduction reaction, the electrochemical water splitting reaction, the nitrogen reduction reaction and the oxygen reduction reaction.

14. The method of claim 13, wherein the electrochemical reaction is the oxygen evolution reaction or the chlorine evolution reaction.

15. The method of claim 1, wherein the heterogeneous electrocatalyst exhibits a lower overpotential or improved specific activity for the chemical reaction than the conductive electrocatalytic substrate.

16. The method of claim 1, wherein the heterogeneous electrocatalyst exhibits has a more favorable surface charge distribution for the chemical reaction than the conductive electrocatalytic substrate.

17. A heterogeneous electrocatalyst made by the method of claim 1.

18. A heterogeneous electrocatalyst comprising a thin film of TiO₂ on a conductive electrocatalytic substrate of IrO₂, FTO, or RuO₂, wherein the thin film of TiO₂ is made from 1 to 15 cycles of an atomic layer deposition process.

19. An electrode comprising the heterogeneous electrocatalyst of claim 18.

20. The electrode of claim 19, wherein the electrode is used to generate reactive chloride species in a wastewater treatment system.
